(19) United States
(12) Patent Application Publication
(10) Pub. No.: US 2026/0371556 A1
(43) Pub. Date: Nov. 19, 2026

(54) SEMICONDUCTOR DEVICE INCLUDING A VERTICAL CHANNEL TRANSISTOR AND METHOD FOR MANUFACTURING THE SAME

(71) Applicant: SAMSUNG ELECTRONICS CO., LTD., Suwon-si (KR)

(72) Inventors: Hyun Jin LEE, Suwon-si (KR); Hui-Jung KIM, Suwon-si (KR); Min Ju KANG, Suwon-si (KR); Su Jin KANG, Suwon-si (KR); Yong Kwan KIM, Suwon-si (KR); Hee Jae CHAE, Suwon-si (KR)

(73) Assignee: SAMSUNG ELECTRONICS CO., LTD., Suwon-si (KR)

(21) Appl. No.: 19/546,734

(22) Filed: Feb. 23, 2026

(30) Foreign Application Priority Data
May 15, 2025 (KR) 10-2025-0063052

(51) Int. Cl. H10B 12/00

(52) U.S. Cl. CPC H10B 12/315; H10B 12/05

(57) ABSTRACT

A semiconductor device includes a word line extending in a first direction; a bit line extending in a second direction, wherein the bit line includes a first conductive pattern, a second conductive pattern disposed on the first conductive pattern, and a metal silicide pattern disposed on the second conductive pattern; an active pattern including a first surface electrically connected to the bit line and a second surface opposite to the first surface in a third direction; and a data storage pattern electrically connected to the second surface of the active pattern, wherein a width of the first conductive pattern in the first direction is different from a width of the second conductive pattern in the first direction.

### CROSS-REFERENCE TO RELATED APPLICATION

This application claims priority from Korean Patent Application No. 10-2025-0063052 filed on May 15, 2025, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor device and a method for manufacturing the same, and more particularly, to a semiconductor device including a vertical channel transistor (VCT) and a method for manufacturing the same.

### 2. Description of Related Art

There is a growing demand to increase the integration density of semiconductor devices in order to meet consumer expectations for high performance and low cost. Since the integration density of the semiconductor devices is a key factor in determining the overall product cost, enhancing the integration density has become a critical requirement.

In two-dimensional (planar) semiconductor devices, the integration density is mainly determined based on an area occupied by a unit memory cell, and is thus highly dependent on the level of fine pattern formation technology. However, as pattern miniaturization requires ultra-high-priced equipment, the integration density of the two-dimensional semiconductor devices, while improving, remains limited. Accordingly, semiconductor devices incorporating vertical channel transistors—where the channel extends in a vertical direction—have been proposed as an alternative.

### SUMMARY

A technical objective of the present disclosure is to provide a semiconductor device with improved product reliability.

Another technical objective of the present disclosure is to provide a method for manufacturing a semiconductor device that enables the production of a semiconductor device with enhanced product reliability.

The technical purposes of the present disclosure are not limited to the above-mentioned technical purposes, and other technical purposes not mentioned may be clearly understood by a person skilled in the art of the present disclosure from the following description.

According to an aspect of the present disclosure, there is provided a semiconductor device including a word line extending in a first direction; a bit line extending in a second direction, wherein the bit line includes a first conductive pattern, a second conductive pattern disposed on the first conductive pattern, and a metal silicide pattern disposed on the second conductive pattern; an active pattern including a first surface electrically connected to the bit line and a second surface opposite to the first surface in a third direction; and a data storage pattern electrically connected to the second surface of the active pattern, wherein a width of the first conductive pattern in the first direction is different from a width of the second conductive pattern in the first direction.

According to the aforementioned and other embodiments of the present disclosure, there is provided a semiconductor device including a word line extending in a first direction; a bit line extending in a second direction, wherein the bit line includes a first sidewall and a second sidewall opposite to each other in the first direction; an active pattern including a first surface electrically connected to the bit line and a second surface opposite to the first surface in a third direction; and a data storage pattern electrically connected to the second surface of the active pattern, wherein at least one of the first sidewall or the second sidewall of the bit line has a step defined by the first direction.

According to the aforementioned and other embodiments of the present disclosure, there is provided a semiconductor device including a word line extending in a first direction; bit lines spaced apart from each other in the first direction and extending in a second direction, wherein each of the bit lines includes a first conductive pattern, a second conductive pattern disposed on the first conductive pattern, and a metal silicide pattern disposed on the second conductive pattern; an active pattern disposed on each of the bit lines; a first isolation pattern disposed between the first conductive patterns adjacent to each other in the first direction; a second isolation pattern disposed on the first isolation pattern and between the second conductive patterns adjacent to each other in the first direction, between the metal silicide patterns adjacent to each other in the first direction, and between the active patterns adjacent to each other in the first direction; and a barrier insulating pattern between the second isolation pattern and the active pattern, wherein a width of the first isolation pattern in the first direction is greater than a width of the second isolation pattern in the first direction.

Specific details of other embodiments are provided in the following detailed description and accompanying drawings.

### BRIEF DESCRIPTION OF DRAWINGS

The above and other aspects and features of the present disclosure will become more apparent by illustrating in detail embodiments thereof with reference to the attached drawings, in which:

FIG. 1 is a layout diagram of a semiconductor device according to some embodiments;

FIG. 2 is a cross-sectional view taken along lines A-A and B-B of FIG. 1;

FIG. 3 is a cross-sectional view taken along lines C-C and D-D of FIG. 1;

FIGS. 4-9 are diagrams illustrating a semiconductor device according to some embodiments, where FIGS. 4, 6, and 8 are cross-sectional views taken along lines A-A and B-B of FIGS. 1, and 5, 7, and FIGS. 5, 7, and 9 are cross-sectional views taken along lines C-C and D-D of FIG. 1;

FIG. 10 is a layout diagram illustrating a semiconductor device according to some embodiments;

FIGS. 11-37 are diagrams illustrating a method for manufacturing a semiconductor device according to some embodiments;

FIGS. 38-45 are diagrams illustrating a method for manufacturing a semiconductor device according to some embodiments;

FIGS. 46 and 47 are diagrams illustrating a method for manufacturing a semiconductor device according to some embodiments;

FIGS. 48-53 are diagrams illustrating a method for manufacturing a semiconductor device according to some embodiments;

FIGS. 54-58 are diagrams illustrating a method for manufacturing a semiconductor device according to some embodiments;

FIGS. 59-62 are diagrams illustrating a method for manufacturing a semiconductor device according to some embodiments;

FIG. 63 is a cross-sectional view illustrating a semiconductor device according to some embodiments; and

FIG. 64 is a cross-sectional view illustrating a semiconductor device according to some embodiments.

### DETAILED DESCRIPTIONS

As used herein, although the terms first, the second, and the like are used to describe various elements or components, it is obvious that these elements or components are not limited by these terms. These terms are merely used to distinguish one element or component from another element or component. Accordingly, it is apparent that a first element or component as mentioned below may be a second element or component within the technical idea of the present disclosure.

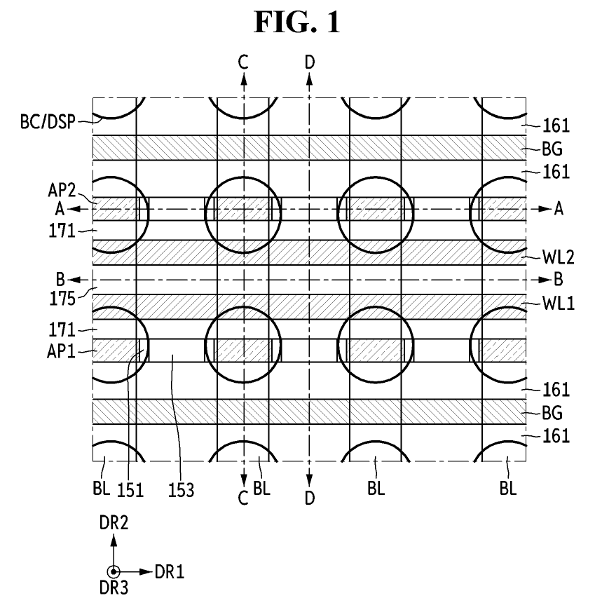

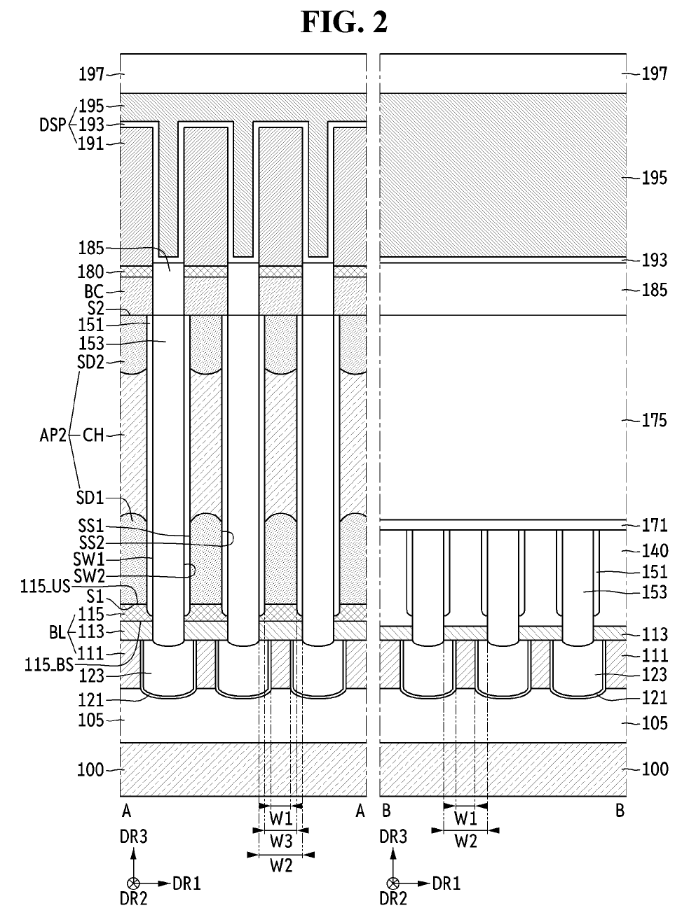

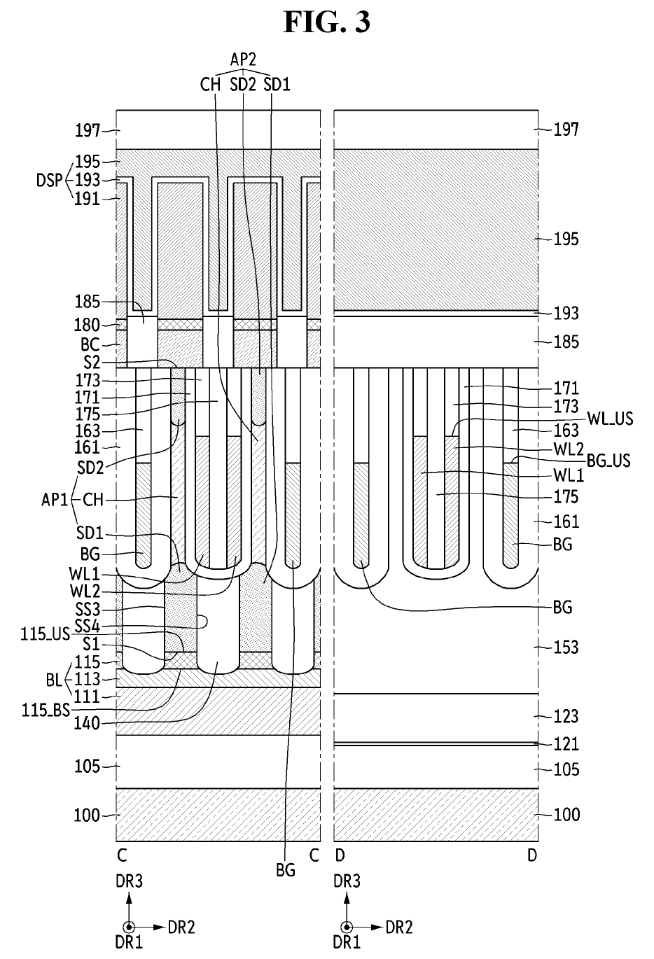

FIG. 1 is a layout diagram of a semiconductor device according to some embodiments. FIG. 2 is a cross-sectional view taken along lines A-A and B-B of FIG. 1. FIG. 3 is a cross-sectional view taken along lines C-C and D-D of FIG. 1.

A semiconductor device according to some embodiments includes memory cells, each including a vertical channel transistor (VCT).

Referring to FIGS. 1-3, the semiconductor device according to some embodiments includes a bit line BL, a word line WL1 and WL2, a back gate electrode BG, an active pattern AP1 and AP2, and a data storage pattern DSP.

A substrate 100 may be a silicon substrate, or may include a material other than silicon, for example, silicon germanium, indium antimonide, lead telluride compound, indium arsenide, indium phosphide, gallium arsenide, or gallium antimonide. In another example, the substrate 100 may include a ceramic substrate, a quartz substrate, or a glass substrate.

An insulating film 105 may be disposed on the substrate 100. The insulating film 105 may be made of an insulating material. The insulating film 105 may be embodied as a single film or a multilayer film.

The memory cells may be disposed on the substrate 100. First to third directions DR1, DR2, and DR3 may intersect each other. The first direction DR1 and the second direction DR2 may be parallel to a front surface of the substrate 100 on which the memory cells are disposed, and the third direction DR3 may be perpendicular to the front surface of the substrate 100. Hereinafter, the upper surface, the upper portion, the lower surface, the lower portion, the bottom surface, and the vertical level are defined based on the third direction DR3.

The bit lines BL may be disposed on the substrate 100. The adjacent bit lines BL may be spaced apart from each other in the first direction DR1. The bit line BL may extend in an elongate manner in the second direction DR2. The bit line BL may include an upper surface and a bottom surface opposite to each other in the third direction DR3. The upper surface of the bit line BL may face the first active pattern AP1 and the second active pattern AP2.

The bit line BL may include a first conductive pattern 111, a second conductive pattern 113, and a metal silicide pattern 115. The first conductive pattern 111 may extend in an elongate manner in the second direction DR2. The first conductive patterns 111 may be spaced apart from each other in the first direction DR1. The second conductive pattern 113 may be disposed on the first conductive pattern 111. The second conductive pattern 113 may extend in an elongate manner in the second direction DR2. The second conductivepatterns 113 may be spaced apart from each other in the first direction DR1. The metal silicide pattern 115 may be disposed on the second conductive pattern 113. The first conductive pattern 111, the second conductive pattern 113, and the metal silicide pattern 115 may be sequentially stacked in the third direction DR3.

A width W1 of the first conductive pattern 111 in the first direction DR1 is different from a width W2 of the second conductive pattern 113 in the first direction DR1. The width W1 of the first conductive pattern 111 in the first direction DR1 is smaller than the width W2 of the second conductive pattern 113 in the first direction DR1. The bit line BL includes a first sidewall and a second sidewall extending in the second direction DR2 and opposite to each other in the first direction DR1, and at least one of the first sidewall or the second sidewall has a step. At least one of the first sidewall or the second sidewall of the bit line BL has the step at an interface between the first conductive pattern 111 and the second conductive pattern 113.

The metal silicide pattern 115 may include a bottom surface 115_BS and an upper surface 115_US opposite to each other in the third direction DR3. The bottom surface 115_BS of the metal silicide pattern 115 may be in contact with the second conductive pattern 113. A width W2 of the bottom surface 115_BS of the metal silicide pattern 115 in the first direction DR1 may be substantially equal to a width W2 of the second conductive pattern 113 in the first direction DR1. The upper surface 115_US of the metal silicide pattern 115 may be in contact with the active pattern AP1 and AP2. The upper surface 115_US of the metal silicide pattern 115 may be in contact with the first surface S1 of the active pattern AP1 or AP2. A width W3 of the upper surface 115_US of the metal silicide pattern 115 in the first direction DR1 may be substantially equal to a width W3 of the first surface S1 of the active pattern AP1 or AP2 in the first direction DR1.

In some embodiments, the width W2 of the bottom surface 115_BS of the metal silicide pattern 115 in the first direction DR1 and the width W3 of the upper surface 115_US of the metal silicide pattern 115 in the first direction DR1 may be different from each other. A width W2 of the bottom surface 115_BS of the metal silicide pattern 115 in the first direction DR1 may be greater than a width W3 of the upper surface 115_US of the metal silicide pattern 115 in the first direction DR1. The metal silicide pattern 115 may include a portion having a width in the first direction DR1 that decreases as the portion extends toward the active pattern AP1 or AP2. The metal silicide pattern 115 may include a first sidewall and a second sidewall that extend in the second direction DR2 and are opposite to each other in the first direction DR1. At least one of the first sidewall or the second sidewall of the metal silicide pattern 115 may have a step. That is, at least one of the first sidewall or the second sidewall of the bit line BL may have a step.

In some embodiments, metal silicide patterns 115 may be spaced apart from each other in the second direction DR2 on the second conductive pattern 113. The metal silicide pattern 115 may be disposed between the second conductive pattern 113 and the active pattern AP1 or AP2 in the third direction DR3, and may not be disposed between the second conductive pattern 113 and a second isolation pattern 140 in the third direction DR3. The upper surface 115_US of the metal silicide pattern 115 may be in contact with the active pattern AP1 or AP2 and may not be in contact with the second isolation pattern 140. An upper surface of the second conductive pattern 113 may be in contact with the second isolation pattern 140. In other words, the second isolation pattern 140 may extend through the metal silicide pattern 115 along the third direction DR3. The second isolation pattern 140 may be disposed between the metal silicide patterns 115 spaced apart from each other in the second direction DR2. The lowermost surface of the second isolation pattern 140 may be disposed in the second conductive pattern 113.

Each of the first conductive pattern 111 and the second conductive pattern 113 may be made of a conductive material including a metal. For example, each of the first conductive pattern 111 and the second conductive pattern 113 may include at least one of a conductive metal nitride, a conductive metal silicon nitride, a metal carbonitride, a conductive metal oxide, a conductive metal silicide, a two-dimensional material, or a metal. The metal silicide pattern 115 may include conductive metal silicide.

A first isolation pattern 121 and 123 may be disposed on the substrate 100. The first isolation pattern 121 and 123 may be disposed between the bit lines BL adjacent to each other in the first direction DR1. The first isolation pattern 121 and 123 may be disposed between the first conductive patterns 111 adjacent to each other in the first direction DR1. The first isolation pattern 121 and 123 may extend in the second direction DR2. The first isolation pattern 121 and 123 may extend in the second direction DR2 and may extend along a first sidewall and a second sidewall of the first conductive pattern 111 opposite to each other in the first direction DR1. The first isolation patterns 121 and 123 may be spaced apart from each other in the first direction DR1. The lowermost surface of the first isolation pattern 121 and 123 may be disposed in the insulating film 105.

The first isolation pattern 121 and 123 may be made of an insulating material. The first isolation pattern 121 and 123 may include, for example, at least one of silicon oxide (SiO₂), silicon nitride (SiN), silicon carbonitride (SiCN), silicon oxynitride (SiON), silicon oxycarbonitride (SiOCN), or a combination thereof. The first isolation pattern 121 and 123 may be embodied as a single film or multiple films. For example, the first isolation pattern 121 and 123 may include a first film 121 and a second film 123. The first film 121 may extend along sidewalls and a bottom surface of the second film 123. The first film 121 may be disposed between the second film 123 and the first conductive pattern 111 and between the second film 123 and the insulating film 105. For example, the first film 121 may include silicon nitride and the second film 123 may include silicon oxide. However, embodiments of the present disclosure are not limited thereto.

The first active patterns AP1 and the second active patterns AP2 may be disposed on each of the bit lines BL. The first active patterns AP1 and the second active patterns AP2 may be alternately arranged with each other along the second direction DR2.

The first active patterns AP1 may be spaced apart from each other in the first direction DR1. The first active patterns AP1 may be spaced apart from each other by a predetermined spacing. The second active patterns AP2 may be spaced apart from each other in the first direction DR1. The second active patterns AP2 may be spaced apart from each other by a predetermined spacing. The first active pattern AP1 may be spaced apart from the second active pattern AP2 in the second direction DR2. The first active patterns AP1 and the second active patterns AP2 may be two-dimensionally arranged along the first direction DR1 and the second direction DR2 intersecting each other.

For example, each of the first active pattern AP1 and the second active pattern AP2 may be made of a single crystal semiconductor material. For example, each of the first active pattern AP1 and the second active pattern AP2 may be made of single crystalline silicon.

Each of the first active pattern AP1 and the second active pattern AP2 includes a first surface S1 and a second surface S2 opposite to each other in the third direction DR3. For example, the first surfaces S1 of the first and second active patterns AP1 and AP2 may face the bit line BL. The second surfaces S2 of the first and second active patterns AP1 and AP2 may face a contact pattern BC.

The first surfaces S1 of the first and second active pattern AP1 and AP2 are electrically connected to the bit line BL. For example, the first surfaces S1 of the first and second active pattern AP1 and AP2 may be in contact with the bit line BL of the bit line BL. The first surfaces S1 of the first and second active pattern AP1 and AP2 may be in contact with the metal silicide pattern 115 of the bit line BL. The second surfaces S2 of the first and second active pattern AP1 and AP2 may be electrically connected to the contact patterns BC. The second surfaces S2 of the first and second active pattern AP1 and AP2 may be in contact with the contact patterns BC.

In some embodiments, the width W3 of the first surface S1 of the first active pattern AP1 in the first direction DR1 may be substantially equal to the width of the second surface S2 of the first active pattern AP1 in the first direction DR1. The width W3 of the first surface S1 of the second active pattern AP2 in the first direction DR1 may be substantially equal to a width of the second surface S2 of the second active pattern AP2 in the first direction DR1. Each of the width W3 of the first surface S1 of the first active pattern AP1 in the first direction DR1 and the width W3 of the first surface S1 of the second active pattern AP2 in the first direction DR1 may be different from the width W2 of the second conductive pattern 113 in the first direction DR1. Each of the width W3 of the first surface S1 of the first active pattern AP1 in the first direction DR1 and the width W3 of the first surface S1 of the second active pattern AP2 in the first direction DR1 may be smaller than the width W2 of the second conductive pattern 113 in the first direction DR1.

The width of the first surface S1 of the first active pattern AP1 in the second direction DR2 may be different from the width of the second surface S2 of the first active pattern AP1 in the second direction DR2. The width of the first surface S1 of the first active pattern AP1 in the second direction DR2 may be greater than the width of the second surface S2 of the first active pattern AP1 in the second direction DR2. The width of the first surface S1 of the second active pattern AP2 in the second direction DR2 may be different from the width of the second surface S2 of the second active pattern AP2 in the second direction DR2. The width of the first surface S1 of the second active pattern AP2 in the second direction DR2 may be greater than the width of the second surface S2 of the second active pattern AP2 in the second direction DR2.

Each of the first active pattern AP1 and the second active pattern AP2 may include a first sidewall SS1 and a second sidewall SS2 opposite to each other in the first direction DR1, and a third sidewall SS3 and a fourth sidewall SS4 opposite to each other in the second direction DR2. The third sidewall SS3 of the first active pattern AP1 may face the fourth sidewall SS4 of the second active pattern AP2.

The fourth sidewall SS4 of the first active pattern AP1 may be adjacent to a first word line WL1. The third sidewall SS3 of the second active pattern AP2 may be adjacent to a second word line WL2.

Each of the first active pattern AP1 and the second active pattern AP2 may include a first dopant area SD1 adjacent to the bit line BL, a second dopant area SD2 adjacent to the contact pattern BC, and a channel area CH between the first dopant area SD1 and the second dopant area SD2. The first dopant area SD1 and the second dopant area SD2 are areas doped with dopants in each of the first active pattern AP1 and the second active pattern AP2. For example, the first and second dopant areas SD1 and SD2 may be doped with P-type dopants, and the channel area CH may not be doped with dopants or may be doped with N-type dopants. In another example, the first and second dopant areas SD1 and SD2 may be doped with an N-type dopant, and the channel area CH may be undoped with a dopant or doped with a P-type dopant.

During an operation of the semiconductor device, the channel area CH of each of the first and second active patterns AP1 and AP2 may be controlled by the first and second word lines WL1 and WL2 and back gate electrodes BG. Since each of the first and second active patterns AP1 and AP2 are made of a single crystal semiconductor material, leakage current characteristics of the semiconductor device may be improved.

The back gate electrodes BG may be disposed on the bit line BL. The back gate electrodes BG may be spaced apart from each other in the second direction DR2. The back gate electrodes BG may be spaced apart from each other by a predetermined spacing. Each back gate electrode BG may extend in the first direction DR1 and across the bit line BL.

Each back gate electrode BG may be disposed between the first active pattern AP1 and the second active pattern AP2 adjacent to each other in the second direction DR2. In other words, the first active pattern AP1 may be disposed on one side of each back gate electrode BG, and the second active pattern AP2 may be disposed on the other side of each back gate electrode BG. A vertical length of the back gate electrode BG in the third direction DR3 may be smaller than a vertical length of each of the first and second active pattern AP1 and AP2 in the third direction DR3.

Each back gate electrode BG may be disposed between the third sidewall SS3 of the first active pattern AP1 and the fourth sidewall SS4 of the second active pattern AP2. Each of the back gate electrodes BG may be disposed on the third sidewall SS3 of the first active pattern AP1 and the fourth sidewall SS4 of the second active pattern AP2.

The first active pattern AP1 may be disposed between the first word line WL1 and the back gate electrode BG. The second active pattern AP2 may be disposed between the second word line WL2 and the back gate electrode BG. A pair of the first word line WL1 and the second word line WL2 may be disposed between the back gate electrodes BG adjacent to each other in the second direction DR2.

The back gate electrode BG may include a conductive material, and may include, for example, at least one of a conductive semiconductor material, a conductive metal nitride, a conductive metal silicon nitride, a metal carbonitride, a conductive metal silicide, a conductive metal oxide, a two-dimensional material, or a metal.

When the semiconductor device operates, a voltage may be applied to the back gate electrode BG, such that a threshold voltage of the vertical channel transistor (VCT) may be adjusted. the threshold voltage of the vertical channel transistor is adjusted, thereby preventing the leakage current characteristic from being deteriorated.

The first word line WL1 and the second word line WL2 may be disposed on the bit line BL. Each of the first word line WL1 and the second word line WL2 may extend in the first direction DR1. The first word lines WL1 and the second word lines WL2 may be alternately arranged with each other along the second direction DR2.

The first word line WL1 may be disposed on the fourth sidewall SS4 of the first active patterns AP1. The second word line WL2 may be disposed on the third sidewall SS3 of the second active patterns AP2. The first active patterns AP1 and the second active patterns AP2 may be disposed between the first word line WL1 and the second word line WL2 adjacent to each other in the second direction DR2.

The first word line WL1 and the second word line WL2 may be spaced apart from the bit line BL and the contact pattern BC in the third direction DR3. The first word line WL1 and the second word line WL2 may be located between the bit line BL and the contact pattern BC.

In some embodiments, each of the first word line WL1 and the second word line WL2 may have a substantially uniform width in the second direction DR2.

The first word line WL1 will be described below by way of example. For example, a vertical length of the first word line WL1 in the third direction DR3 may be greater than a vertical length of the back gate electrode BG in the third direction DR3. In another example, the vertical length of the first word line WL1 in the third direction DR3 may be equal to the vertical length of the back gate electrode BG in the third direction DR3. In still another example, the vertical length of the first word line WL1 in the third direction DR3 may be smaller than the vertical length of the back gate electrode BG in the third direction DR3.

In addition, in one example, based on the bit line BL (or in the third direction DR3), a vertical level of the upper surface WL_US of the first word line WL1 may be higher than a vertical level of the upper surface BG_US of the back gate electrode BG. In another example, based on the bit line BL, the vertical level of the upper surface WL_US of the first word line WL1 may be equal to the vertical level of the upper surface BG_US of the back gate electrode BG. In still another example, based on the bit line BL, a vertical level of the upper surface WL_US of the first word line WL1 may be lower than a vertical level of the upper surface BG_US of the back gate electrode BG.

In addition, in one example, a vertical level of the bottom surface of the first word line WL1 may be higher than a vertical level of the bottom surface of the back gate electrode BG based on the bit line BL. In another example, based on the bit line BL, the vertical level of the bottom surface of the first word line WL1 may be equal to the vertical level of the bottom surface of the back gate electrode BG. In still another example, based on the bit line BL, a vertical level of the bottom surface of the first word line WL1 may be lower than a vertical level of the bottom surface of the back gate electrode BG.

For example, each of the bottom surface of each of the first and second word lines WL1 and WL2 and the bottom surface of the back gate electrode BG may be convexly rounded. However, embodiments of the present disclosure are not limited thereto. For example, each of the upper surfaces WL_US of the first and second word lines WL1 and WL2 and the upper surface BG_US of the back gate electrode BG may be flat. However, embodiments of the present disclosure are not limited thereto.

The second isolation pattern 140 may be disposed between the active patterns AP1 and AP2 adjacent to each other in the second direction DR2. The second isolation pattern 140 may be disposed between the third sidewall SS3 of the first active pattern AP1 and the fourth sidewall SS4 of the second active pattern AP2, and between the fourth sidewall SS4 of the first active pattern AP1 and the third sidewall SS3 of the second active pattern AP2, along the second direction DR2. The second isolation pattern 140 may be disposed between the bit line BL and the back gate electrode BG along the third direction DR3. The second isolation pattern 140 may be disposed between the bit line BL and the word lines WL1 and WL2 in the third direction DR3. The second isolation pattern 140 may be disposed on the bottom surface of the back gate electrode BG. The second isolation pattern 140 may be disposed on the bottom surfaces of the word line WL1 and WL2.

The second isolation pattern 140 may be made of an insulating material. The second isolation pattern 140 may be embodied as a single film or multiple films.

A third isolation pattern 153 may be disposed between the first or second active patterns AP1 or AP2 that are adjacent to each other in the first direction DR1. The third isolation pattern 153 may be disposed between the first active patterns AP1 that are adjacent to each other in the first direction DR1, and between the second active patterns AP2 that are adjacent to each other in the first direction DR1. The third isolation pattern 153 may be disposed between the second conductive patterns 113 that are adjacent to each other in the first direction DR1, and between the metal silicide patterns 115 that are adjacent to each other in the first direction DR1.

The third isolation pattern 153 may be disposed between the second isolation patterns 140 that are adjacent to each other in the first direction DR1. The third isolation pattern 153 may extend in the second direction DR2. The third isolation patterns 153 may be spaced apart from each other in the first direction DR1. Between the first or second active patterns AP1 or AP2 that are adjacent to each other in the first direction DR1, the third isolation pattern 153 may be disposed between the back gate electrode BG and the first word line WL1 that are adjacent to each other in the second direction DR2, and between the back gate electrode BG and the second word line WL2 adjacent to each other in the second direction DR2.

The lowermost surface of the third isolation pattern 153 may be disposed in the first isolation pattern 121 and 123. A width of the third isolation pattern 153 in the first direction DR1 may be smaller than a width of the first isolation pattern 121 and 123 in the first direction DR1. The third isolation pattern 153 may be disposed between the first isolation pattern 121 and 123 and the back gate electrode BG along the third direction DR3. The third isolation pattern 153 may be disposed between the first isolation pattern 121 and 123 and the word lines WL1 and WL2 along the third direction DR3. The third isolation pattern 153 may be disposed on the bottom surface of the back gate electrode BG. The third isolation pattern 153 may be disposed on the bottom surfaces of the word lines WL1 and WL2.

A barrier insulating pattern 151 may be disposed between the third isolation pattern 153 and the first or second active pattern AP1 or AP2, and between the third isolation pattern 153 and the second isolation pattern 140. The third isolation pattern 153 may include a first sidewall SW1 and a second sidewall SW2 opposite to each other in the first direction DR1. The barrier insulating pattern 151 may extend along a portion of the first sidewall SW1 and a portion of the second sidewall SW2 of the third isolation pattern 153. The barrier insulating pattern 151 may extend along an upper portion of the first sidewall SW1 and an upper portion of the second sidewall SW2 of the third isolation pattern 153. The barrier insulating pattern 151 may not cover a lower portion of the first sidewall SW1 and a lower portion of the second sidewall SW2 and a bottom surface of the third isolation pattern 153. A vertical level of a bottom surface of the barrier insulating pattern 151 may be higher than a vertical level of a bottom surface of the third isolation pattern 153 based on the bit line BL.

The barrier insulating pattern 151 may be spaced apart from the second conductive pattern 113. A vertical level of the bottom surface of the barrier insulating pattern 151 may be higher than a vertical level of an upper surface of the second conductive pattern 113 based on the bit line BL.

In some embodiments, the barrier insulating pattern 151 may extend along the entirety of the first sidewall SS1 and the entirety of the second sidewall SS2 of each of the active patterns AP1 and AP2. The barrier insulating pattern 151 may be in contact with the metal silicide pattern 115. A bottom surface of the barrier insulating pattern 151 may be disposed in the metal silicide pattern 115 and the second isolation pattern 140. Due to the barrier insulating pattern 151, a width of an upper portion of the metal silicide pattern 115 in the first direction DR1 may be smaller than a width of a lower portion of the metal silicide pattern 115 in the first direction DR1. Due to the barrier insulating pattern 151, each of both sidewalls of the metal silicide pattern 115 opposite to each other in the first direction DR1 may have a step.

Each of the third isolation pattern 153 and the barrier insulating pattern 151 may be made of an insulating material. For example, each of the third isolation pattern 153 and the barrier insulating pattern 151 may include silicon oxide. However, embodiments of the present disclosure are not limited thereto.

A back gate capping pattern 163 may be disposed on the upper surface BG_US of the back gate electrode BG. The back gate capping pattern 163 may cover the upper surface BG_US of the back gate electrode BG. The back gate capping pattern 163 may extend in the first direction DR1 and in a parallel manner to the back gate electrode BG. The back gate capping pattern 163 may be disposed between the first active pattern AP1 and the second active pattern AP2 adjacent to each other in the second direction DR2.

A gate capping pattern 173 may be disposed on the upper surfaces WL_US of the first and second word lines WL1 and WL2. The gate capping pattern 173 may cover the upper surfaces WL_US of the first and second word lines WL1 and WL2. The gate capping pattern 173 may extend in the first direction DR1 and in parallel with the first and second word lines WL1 and WL2. The gate capping pattern 173 may be disposed between the first active pattern AP1 and the second active pattern AP2 adjacent to each other in the second direction DR2.

Each of the back gate capping pattern 163 and the gate capping pattern 173 may be made of an insulating material. Each of the back gate capping pattern 163 and the gate capping pattern 173 may include, for example, a silicon oxide film, a silicon oxynitride film, or a silicon nitride film. However, embodiments of the present disclosure are not limited thereto.

A gate isolation pattern 175 may be disposed on the second isolation pattern 140 and the third isolation pattern 153. The gate isolation pattern 175 may be disposed between the first word line WL1 and the second word line WL2 adjacent in the second direction DR2, and between the gate capping patterns 173 adjacent in the second direction DR2. The first word line WL1 and the second word line WL2 may be isolated from each other via the gate isolation pattern 175. The gate isolation pattern 175 may extend in the first direction DR1 while being disposed between the first word line WL1 and the second word line WL2.

The gate isolation pattern 175 may be made of an insulating material. The gate isolation pattern 175 may be embodied as a single film or a stack of multiple films.

A back gate insulating pattern 161 may be disposed between the back gate electrode BG and the first active pattern AP1, between the back gate electrode BG and the second active pattern AP2, between the back gate electrode BG and the second isolation pattern 140, and between the back gate electrode BG and the third isolation pattern 153. The back gate insulating pattern 161 may extend in the first direction DR1 and in parallel to the back gate electrode BG. The back gate insulating pattern 161 may be disposed between the back gate capping pattern 163 and the first active pattern AP1, between the back gate capping pattern 163 and the second active pattern AP2, and between the back gate capping pattern 163 and the third isolation pattern 153.

A gate insulating pattern 171 may be disposed between the first word line WL1 and the first active pattern AP1, between the second word line WL2 and the second active pattern AP2, between the first word line WL1 and the second isolation pattern 140, between the second word line WL2 and the second isolation pattern 140, between the first word line WL1 and the third isolation pattern 153, and between the first word line WL1 and the third isolation pattern 153. The gate insulating pattern 171 may extend in the first direction DR1 and in parallel with the first word line WL1 and the second word line WL2. The gate insulating pattern 171 may be disposed between the gate capping pattern 173 and the first active pattern AP1, between the gate capping pattern 173 and the second active pattern AP2, and between the gate capping pattern 173 and the third isolation pattern 153. A vertical level of a bottom surface of the back gate insulating pattern 161 may be higher than a vertical level of a bottom surface of the gate insulating pattern 171 based on the bit line BL.

The back gate insulating pattern 161 may extend along an upper portion of the third sidewall SS3 of the first active pattern AP1, and may extend along an upper portion of the fourth sidewall SS4 of the second active pattern AP2. The gate insulating pattern 171 may extend along an upper portion of the fourth sidewall SS4 of the first active pattern AP1, and may extend along an upper portion of the third sidewall SS3 of the second active pattern AP2. Due to the back gate insulating pattern 161 and the gate insulating pattern 171, the width of the upper portion of the first and second active pattern AP1 and AP2 in the second direction DR2 may be smaller than the width of the lower portion of the first and second active pattern AP1 and AP2 in the second direction DR2. Each of the third and fourth sidewalls SS3 and SS4 of each of the first and second active pattern AP1 and AP2 may have a step.

Each of the back gate insulating pattern 161 and the gate insulating pattern 171 may be made of an insulating material. Each of the back gate insulating pattern 161 and the gate insulating pattern 171 may include, for example, a silicon oxide film, a silicon oxynitride film, a high-k dielectric film having a higher dielectric constant than that of the silicon oxide film, or a combination thereof.

A first interlayer insulating film 185 may be disposed on the first and second active patterns AP1 and AP2. The contact pattern BC and a contact silicide pattern 180 may be disposed in the first interlayer insulating film 185. The contact patterns BC and the contact silicide patterns 180 may be electrically connected to each of the first active pattern AP1 and the second active pattern AP2. Each of the contact patterns BC may have various shapes such as a circle, an oval, a rectangle, a square, a rhombus, a hexagon, and the like in a plan view. The contact silicide pattern 180 may be disposed on the contact pattern BC. Alternatively, a landing pad may be further disposed between the contact silicide pattern 180 and the contact pattern BC.

The contact pattern BC may include a conductive material. The contact pattern BC may include, for example, at least one of doped polysilicon, conductive metal nitride, conductive metal silicon nitride, metal carbonitride, conductive metal oxide, conductive metal silicide, a two-dimensional material, or a metal. The contact silicide pattern 180 may include conductive metal silicide.

Data storage patterns DSP may be disposed on the contact patterns BC, respectively. The data storage patterns DSP may be electrically connected to each of the first and second active pattern AP1 and AP2. The data storage patterns DSP may be arranged in a matrix form along the first direction DR1 and the second direction DR2. Each of the data storage patterns DSP may entirely or partially overlap each of the contact patterns BC in the third direction DR3.

For example, the data storage pattern DSP may act as a capacitor. The data storage patterns DSP may include storage electrodes 191, a plate electrode 195 and a capacitor dielectric film 193 interposed between the storage electrodes 191 and the plate electrode 195. The storage electrode 191 may be disposed on the contact pattern BC. The contact silicide pattern 180 may be disposed between the contact pattern BC and the storage electrode 191. For example, the storage electrode 191 may be in contact with the contact silicide pattern 180. In a plan view, the storage electrode 191 may have various shapes such as a circle, an oval, a rectangle, a square, a rhombus, and a hexagon. Each of the data storage patterns DSP may be in contact with an entirety or a portion of the upper surface of the contact silicide pattern 180.

Each of the storage electrode 191 and the plate electrode 195 may include, for example, at least one of a conductive semiconductor material, a conductive metal nitride, a conductive metal silicon nitride, a metal carbonitride, a conductive metal silicide, a conductive metal oxide, or a metal. The capacitor dielectric film 193 may include at least one of a ferroelectric material, an antiferroelectric material, or a paraelectric material. For example, the capacitor dielectric film 193 may include one of a ferroelectric material, an anti-ferroelectric material, a paraelectric material, a combination of a ferroelectric material and an anti-ferroelectric material, a combination of a ferroelectric material and a paraelectric material, a combination of a paraelectric material and an anti-ferroelectric material, a combination of a ferroelectric material, an anti-ferroelectric material, and a paraelectric material.

Alternatively, each of the data storage patterns DSP may act as a variable resistance pattern that may be switched to two resistance states under an electrical pulse applied to a memory element. For example, the data storage pattern DSP may include a phase-change material whose crystal state changes according to the amount of current, perovskite compounds, a transition metal oxide, magnetic materials, ferromagnetic materials, or antiferromagnetic materials.

A second interlayer insulating film 197 may be disposed on the first interlayer insulating film 185. The second interlayer insulating film 197 may be disposed on the data storage patterns DSP. The second interlayer insulating film 197 may cover a surface of the data storage pattern DSP. Each of the first interlayer insulating film 185 and the second interlayer insulating film 197 may be made of an insulating material.

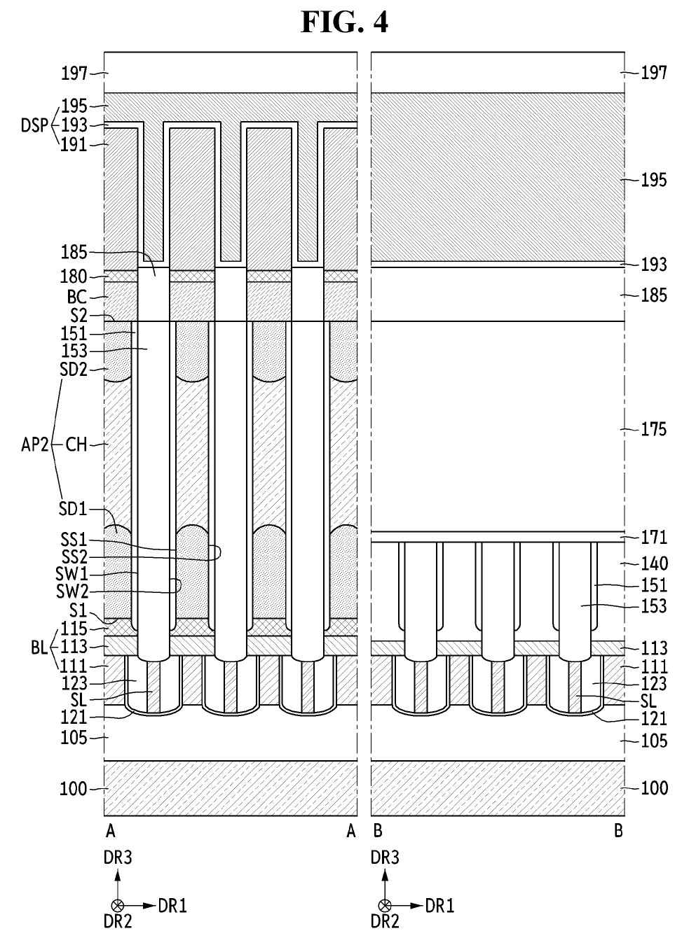

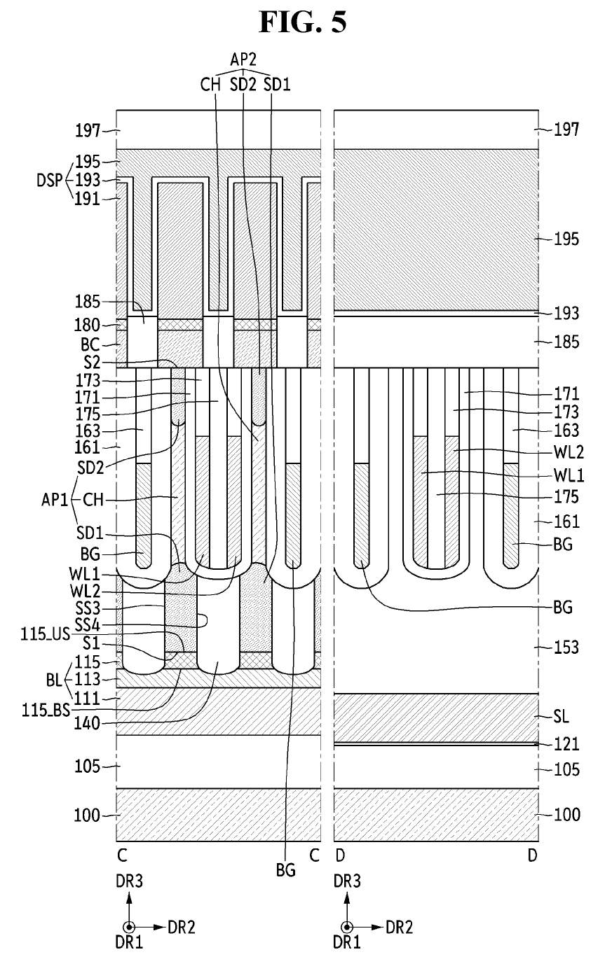

FIGS. 4-9 are diagrams illustrating a semiconductor device according to some embodiments. For convenience of description, differences from those described above with reference to FIGS. 1-3 will be mainly described. For reference, FIGS. 4, 6, and 8 are cross-sectional views taken along lines A-A and B-B of FIG. 1, and FIGS. 5, 7, and 9 are cross-sectional views taken along lines C-C and D-D of FIG. 1.

Referring to FIGS. 4 and 5, the semiconductor device according to some embodiments may further include a shielding conductive pattern SL. The shielding conductive pattern SL may be disposed between the bit lines BL adjacent to each other in the first direction DR1. The shielding conductive patterns SL may be spaced apart from each other in the first direction DR1. The bit line BL may be disposed between the shielding conductive patterns SL adjacent to each other in the first direction DR1.

The shielding conductive pattern SL may overlap a portion of the bit line BL in the first direction DR1. The shielding conductive pattern SL may be disposed between the first conductive patterns 111 adjacent to each other in the first direction DR1. The shielding conductive pattern SL may extend in the second direction DR2 and along a long sidewall of the first conductive pattern 111. The shielding conductive pattern SL may overlap the first conductive pattern 111 in the first direction DR1. The shielding conductive pattern SL may not overlap the second conductive pattern 113 and the metal silicide pattern 115 in the first direction DR1. A vertical level of an upper surface of the shielding conductive pattern SL may be lower than a vertical level of the upper surface of the first conductive pattern 111 in the third direction DR3.

The shielding conductive pattern SL may be disposed in the first isolation pattern 121 and 123. The first isolation pattern 121 and 123 may be disposed between the shielding conductive pattern SL and the bit line BL adjacent to each other in the first direction DR1. The shielding conductive pattern SL may be disposed between the insulating film 105 and the third isolation pattern 153 in the third direction DR3. The shielding conductive pattern SL may not be disposed on the bottom surface of the bit line BL.

The shielding conductive pattern SL includes a conductive material. The shielding conductive pattern SL may include, for example, at least one of conductive metal nitride, conductive metal silicon nitride, metal carbonitride, conductive metal silicide, conductive metal oxide, two-dimensional material, or metal.

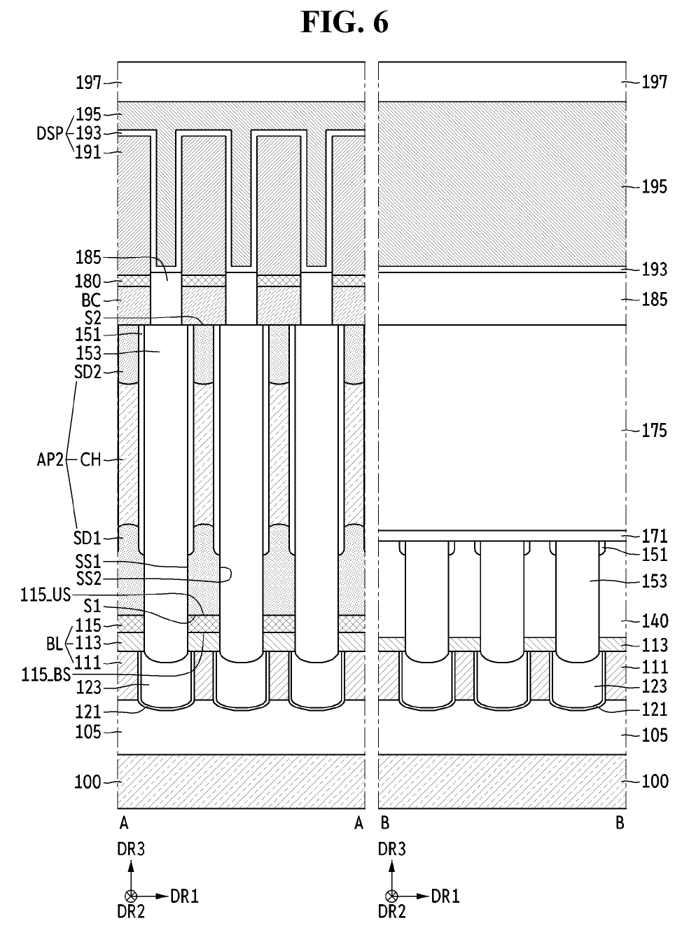

Referring to FIGS. 6-9, in the semiconductor device according to some embodiments, the barrier insulating pattern 151 may extend along a portion of the first sidewall SS1 and a portion of the second sidewall SS2 of the active pattern AP1 and AP2. The barrier insulating pattern 151 may extend along an upper portion of the first sidewall SS1 and an upper portion of the second sidewall SS2 of the active pattern AP1 and AP2. The barrier insulating pattern 151 may be spaced apart from the metal silicide pattern 115. A bottom surface of the barrier insulating pattern 151 may be disposed in the active pattern AP1 and AP2 and the second isolation pattern 140. Due to the barrier insulating pattern 151, a width of an upper portion of the active pattern AP1 and AP2 in the first direction DR1 may be smaller than a width of a lower portion of the active pattern AP1 and AP2 in the first direction DR1. Due to the barrier insulating pattern 151, each of the first sidewall SS1 and the second sidewall SS2 of the active pattern AP1 and AP2 may have a step.

A width of the bottom surface 115_BS of the metal silicide pattern 115 in the first direction DR1 may be substantially equal to a width of the upper surface 115_US of the metal silicide pattern 115 in the first direction DR1.

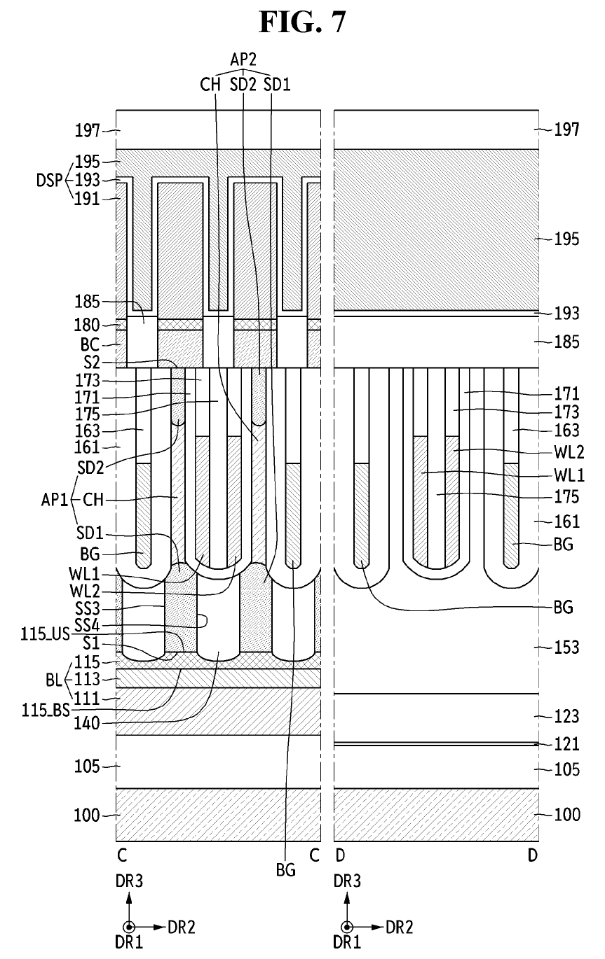

Referring to FIGS. 6 and 7, in some embodiments, the metal silicide pattern 115 may extend in the second direction DR2 and along the second conductive pattern 113. The metal silicide pattern 115 may be disposed between the second conductive pattern 113 and the active pattern AP1 and AP2 and between the second conductive pattern 113 and the second isolation pattern 140. An upper surface of the metal silicide pattern 115 may be in contact with the active pattern AP1 and AP2 and the second isolation pattern 140. An upper surface of the second conductive pattern 113 may be spaced apart from the second isolation pattern 140. In other words, the second isolation pattern 140 may extend through a portion of the metal silicide pattern 115. The lowermost surface of the second isolation pattern 140 may be disposed in the metal silicide pattern 115.

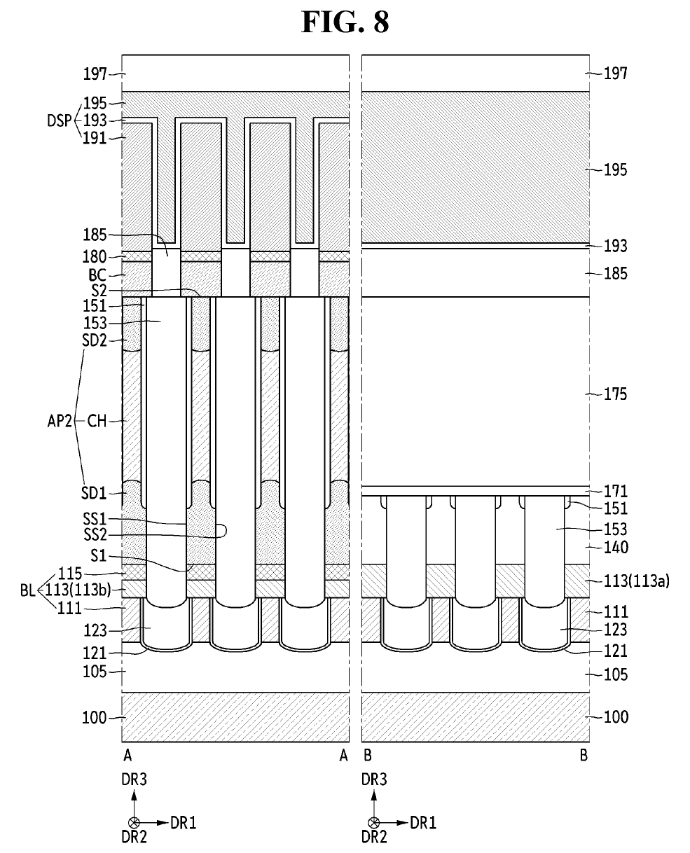

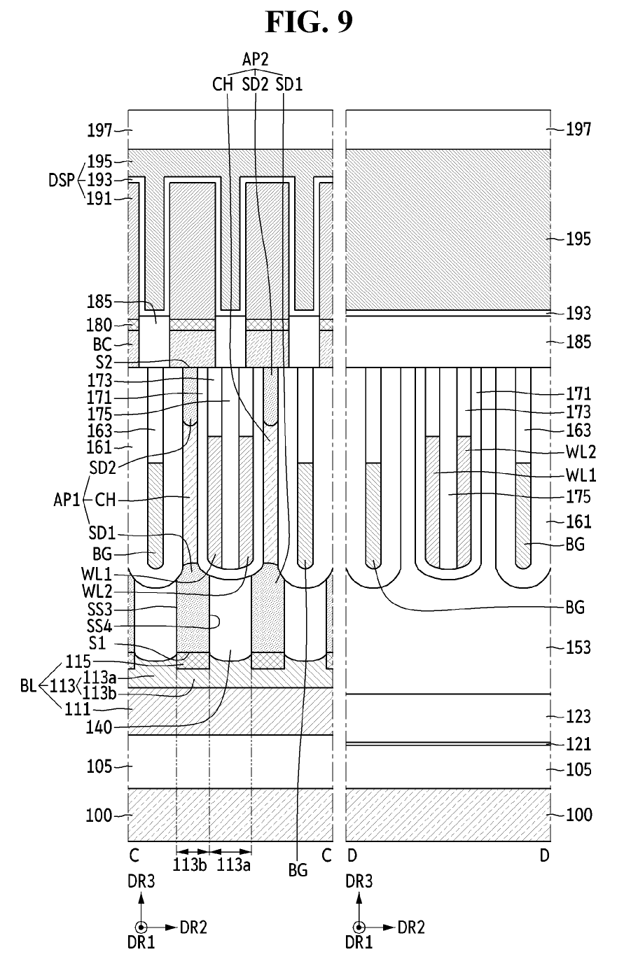

Referring to FIGS. 8 and 9, in some embodiments, the second conductive pattern 113 may include a first portion 113a and a second portion 113b. A vertical length of the first portion 113a in the third direction DR3 may be greater than a vertical length of the second portion 113b in the third direction DR3. The first portion 113a may be disposed on the second isolation pattern 140, and the second portion 113b may be disposed on the active pattern AP1 and AP2. The first portions 113a and the second portions 113b may be alternately arranged with each other along the second direction DR2. The metal silicide pattern 115 may be disposed between the first portions 113a adjacent to each other in the second direction DR2.

A bottom surface of the first portion 113a and a bottom surface of the second portion 113b may be coplanar with each other, while a vertical level of an upper surface of the first portion 113a may be higher than a vertical level of an upper surface of the second portion 113b. The upper surface of the first portion 113a may be coplanar with the upper surface of the metal silicide pattern 115.

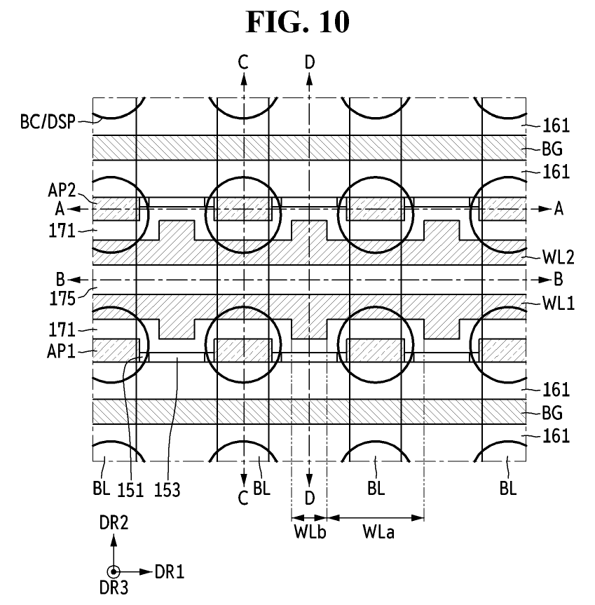

FIG. 10 is a diagram illustrating a semiconductor device according to some embodiments. For convenience of description, differences from those described above with reference to FIGS. 1-9 will be mainly described.

Referring to FIG. 10, in the semiconductor device according to some embodiments, each of the first word line WL1 and the second word line WL2 may include a first portion WLa and a second portion WLb. A width of the first portion WLa in the second direction DR2 may be smaller than a width of the second portion WLb in the second direction DR2.

The first portions WLa and the second portions WLb may be alternately arranged with each other along the first direction DR1. Each of the first active patterns AP1 may be disposed between the second portions WLb of the first word line WL1 adjacent in the first direction DR1. Each of the second active patterns AP2 may be disposed between the second portions WLb of the second word line WL2 adjacent in the first direction DR1.

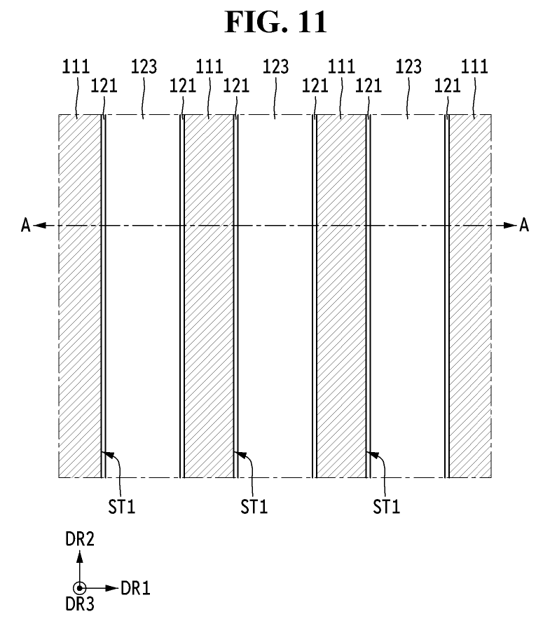

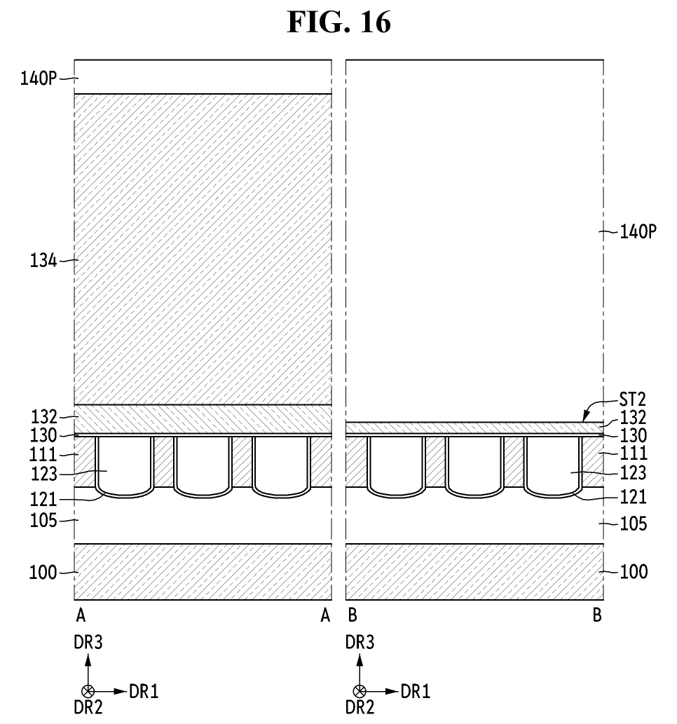

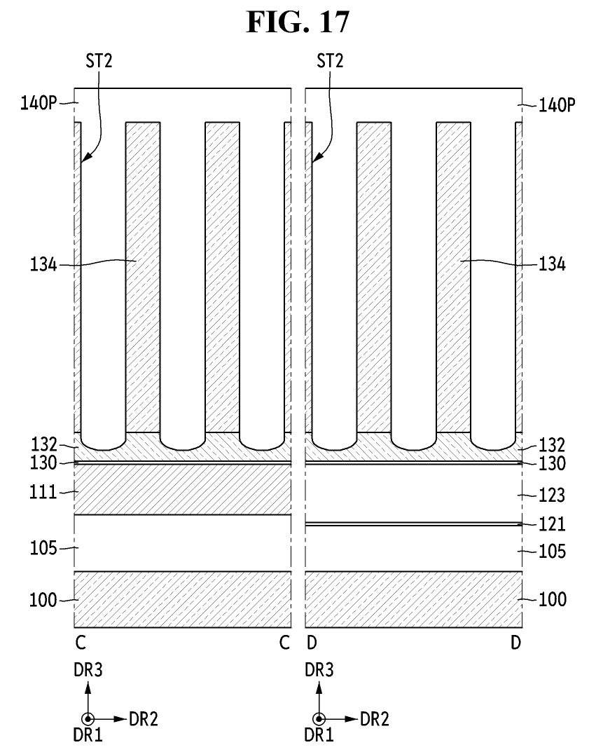

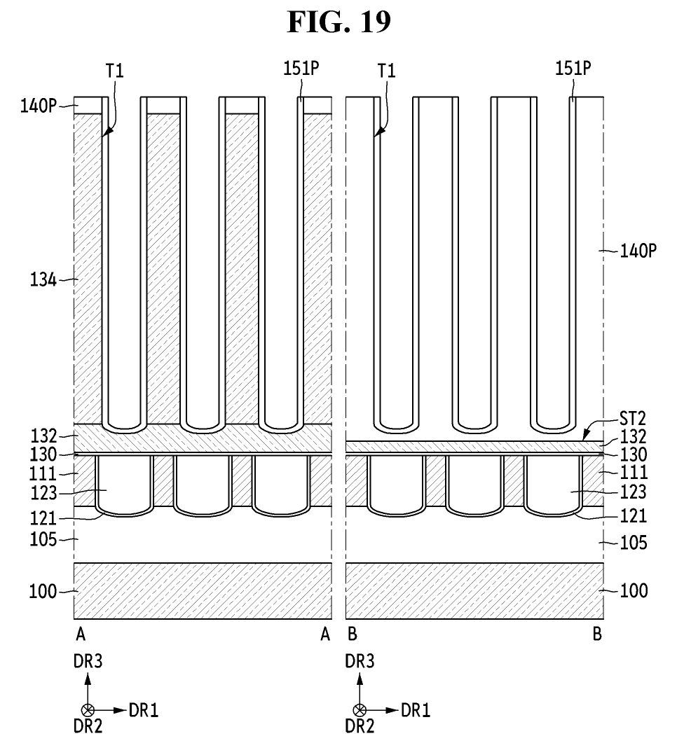

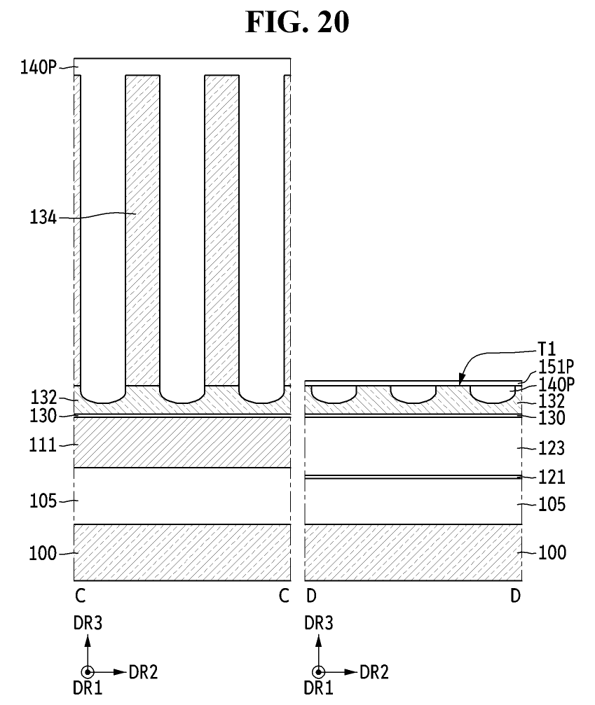

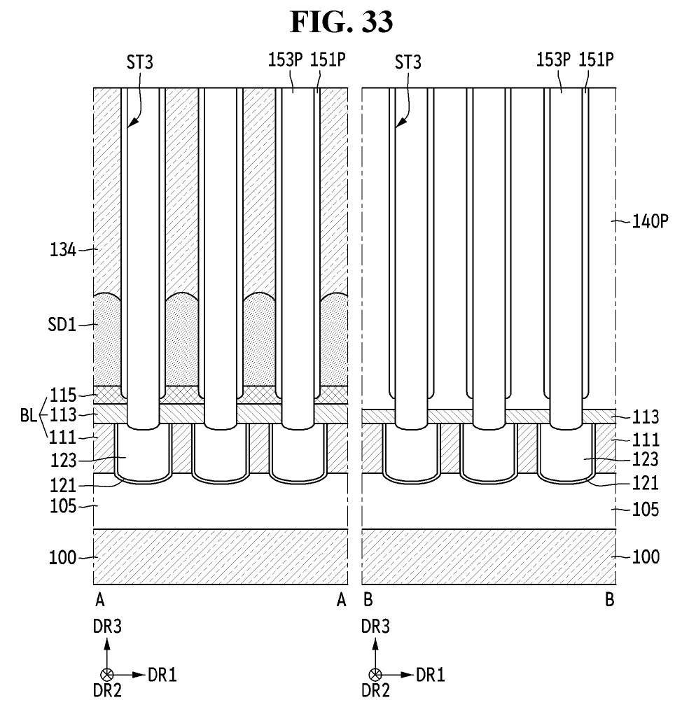

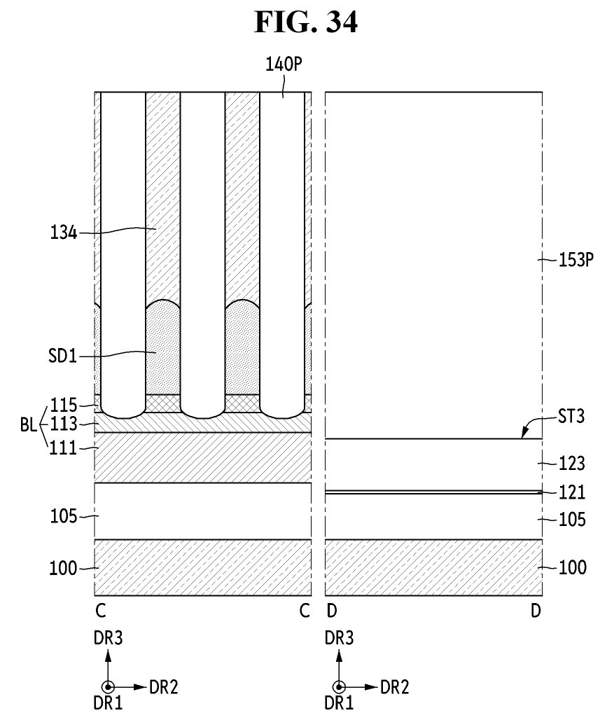

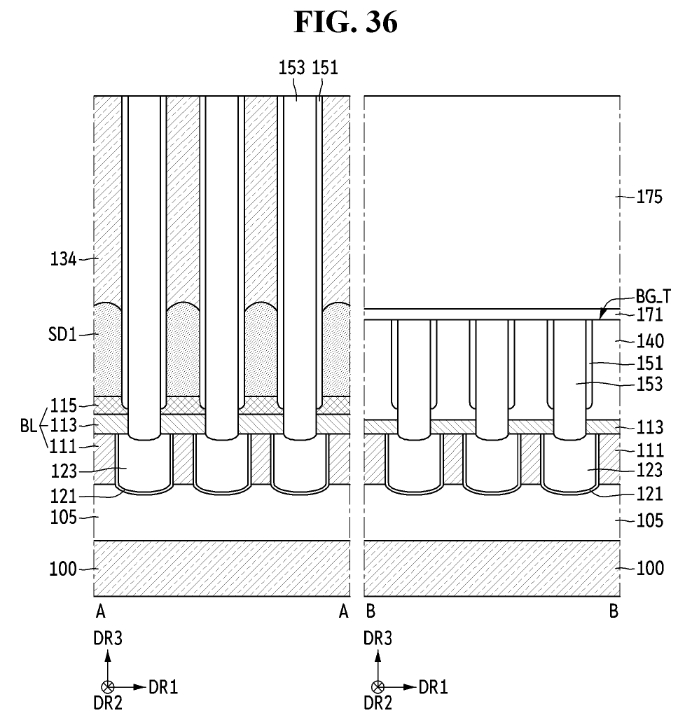

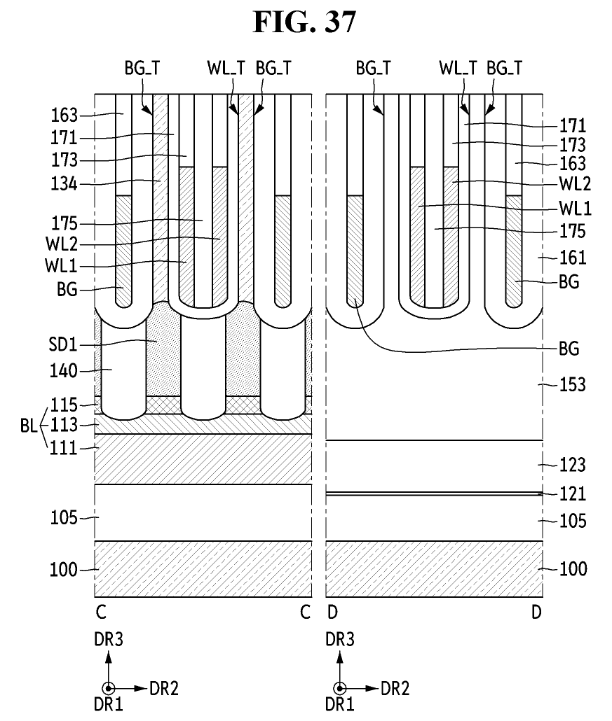

FIGS. 11 to 37 are diagrams illustrating a method for manufacturing a semiconductor device according to some embodiments.

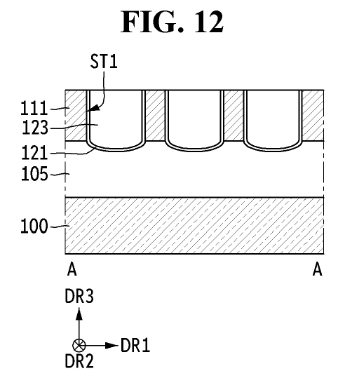

Referring to FIGS. 11 and 12, the insulating film 105 may be formed on the substrate 100. The insulating film 105 may cover a front surface of the substrate 100.

The first conductive pattern 111 and the first isolation pattern 121 and 123 may be formed on the insulating film 105.

For example, a preliminary conductive film may be formed on the insulating film 105. The preliminary conductive film may be formed using, for example, a physical vapor deposition (PVD) method. First isolation trenches ST1 extending in the second direction DR2 and spaced apart from each other in the first direction DR1 may be formed in the preliminary conductive film. The first conductive patterns 111 spaced apart from each other in the first direction DR1 may be formed via the first isolation trench ST1. The first conductive pattern 111 may extend in the second direction DR2. The first isolation trench ST1 may expose the insulating film 105.

Subsequently, the first isolation pattern 121 and 123 may be formed in the first isolation trench ST1. For example, the first film 121 may be formed along the sidewalls and the bottom surface of the first isolation trench ST1. The second film 123 may be formed on the first film 121. The second film 123 may fill the first isolation trench ST1. Subsequently, a planarization process may be performed on the first isolation pattern 121 and 123 and the first conductive pattern 111. Accordingly, the upper surface of the first isolation pattern 121 and 123 may be coplanar with the upper surface of the first conductive pattern 111.

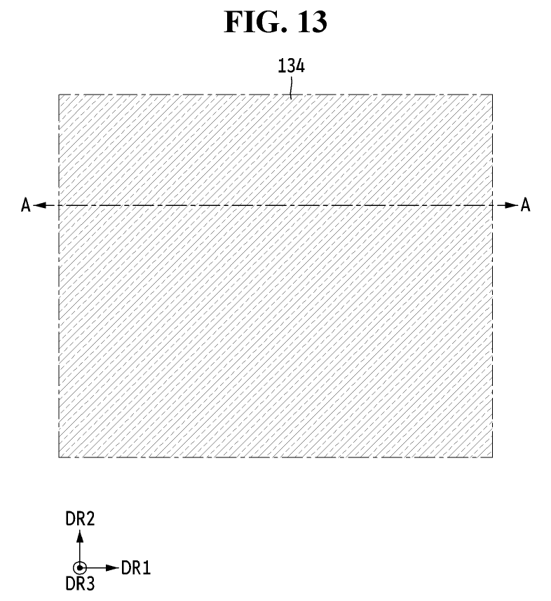

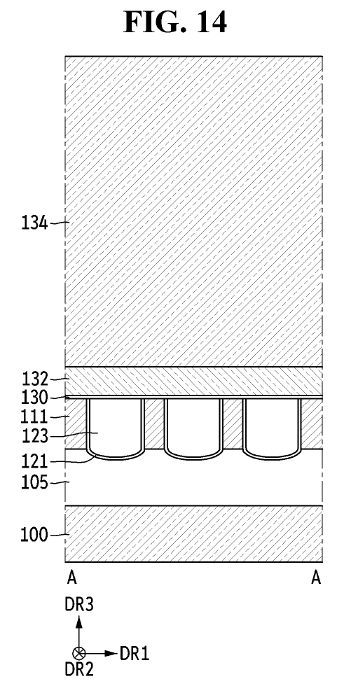

Referring to FIGS. 13 and 14, the barrier conductive film 130 may be formed on the first isolation pattern 121 and 123 and the first conductive pattern 111. The barrier conductive film 130 may extend along the upper surface of the first isolation pattern 121 and 123 and the upper surface of the first conductive pattern 111. The barrier conductive film 130 may be made of a conductive material. The barrier conductive film 130 may include, for example, tungsten nitride.

Subsequently, a sacrificial film 132 and an active film 134 may be formed on the barrier conductive film 130. The sacrificial film 132 may be formed on the barrier conductive film 130, and the active film 134 may be formed on the sacrificial film 132. The sacrificial film 132 may include silicon germanium, and the active film 134 may include single crystalline silicon.

In some embodiments, the sacrificial film 132 may be formed using a chemical vapor deposition (CVD) method.

In some embodiments, after the sacrificial film 132 is formed, an annealing process or an epitaxial growth process may be performed thereon to form the active film 134. In some embodiments, after the amorphous silicon layer is formed, an annealing process and/or a metal induced crystallization process may be performed thereon to form the active film 134 that is made of single crystalline silicon.

Although not shown, an element isolation film may be formed in the active film 134, the sacrificial film 132, the barrier conductive film 130, and the first conductive pattern 111. The substrate 100 may include a first area in which the element isolation film is formed and a second area in which the element isolation film is not formed. The memory cells may be formed in the first area. An end of the first conductive pattern 111 in the second direction DR2 may be disposed on the second area.

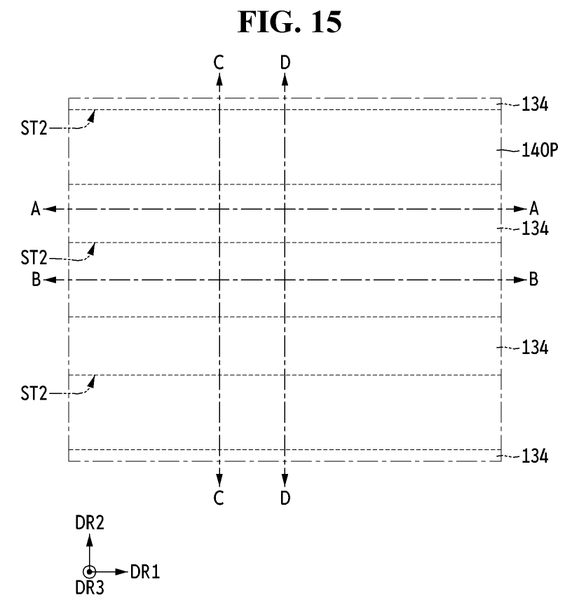

Referring to FIGS. 15-17, second isolation trenches ST2 extending in the first direction DR1 and spaced apart from each other in the second direction DR2 may be formed in the sacrificial film 132 and the active film 134. Portions of the active film 134 may be spaced apart from each other in the second direction DR2 due to the formation of the second isolation trench ST2 and each of the portions of the active film 134 may extend in the first direction DR1.

In some embodiments, a bottom surface of the second isolation trench ST2 may be disposed in the sacrificial film 132. In the process of forming the second isolation trench ST2, the sacrificial film 132 may be used as an etch stop film. The second isolation trench ST2 may be spaced apart from the barrier conductive film 130.

Subsequently, a preliminary isolation film 140P filling the second isolation trench ST2 and covering the active film 134 may be formed. A planarization process may be performed on the preliminary isolation film 140P. The preliminary isolation film 140P may be spaced apart from the barrier conductive film 130. The preliminary isolation film 140P may include, for example, silicon oxide.

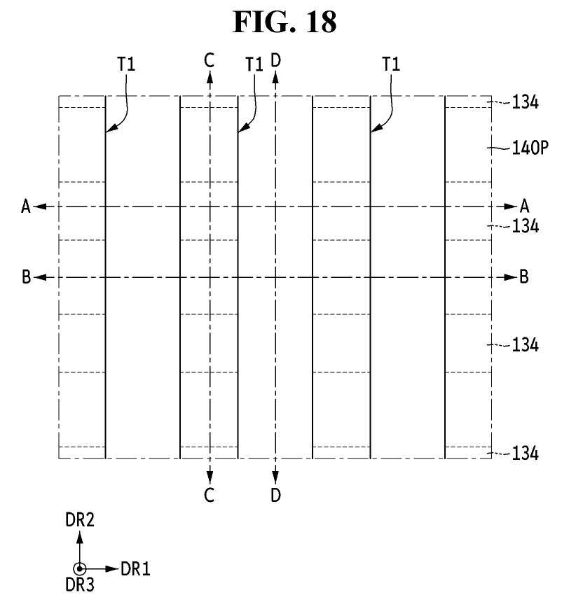

Referring to FIGS. 18-20, first trenches T1 extending in the second direction DR2 and spaced apart from each other in the first direction DR1 may be formed in the sacrificial film 132, the active film 134, and the preliminary isolation film 140P. The first trench T1 may intersect the second isolation trench ST2. The portions of the active film 134 may be spaced apart from each other in the first direction DR1 due to the formation of the first trench T1. That is, the portions of the active film 134 may be spaced apart from each other in the first direction DR1 and the second direction DR2. A vertical level of a bottom surface of the first trench T1 may be higher than a vertical level of a bottom surface of the second isolation trench ST2 based on the front surface of the substrate 100 on which the first conductive pattern 111 has been formed. Based on the front surface of the substrate 100 on which the first conductive pattern 111 has been formed, a vertical level of the bottom surface of the first trench T1 may be lower than a vertical level of the uppermost surface of the sacrificial film 132 and may be higher than a vertical level of the lowermost surface of the preliminary isolation film 140P.

Subsequently, a preliminary barrier insulating film 151P may be formed along the bottom surface and sidewalls of the first trench T1. The active film 134 may include a first sidewall and a second sidewall opposite to each other in the first direction DR1, and the preliminary barrier insulating film 151P may extend along the entire first sidewall and the entire second sidewall of the active film 134. The preliminary barrier insulating film 151P may include, for example, silicon oxide.

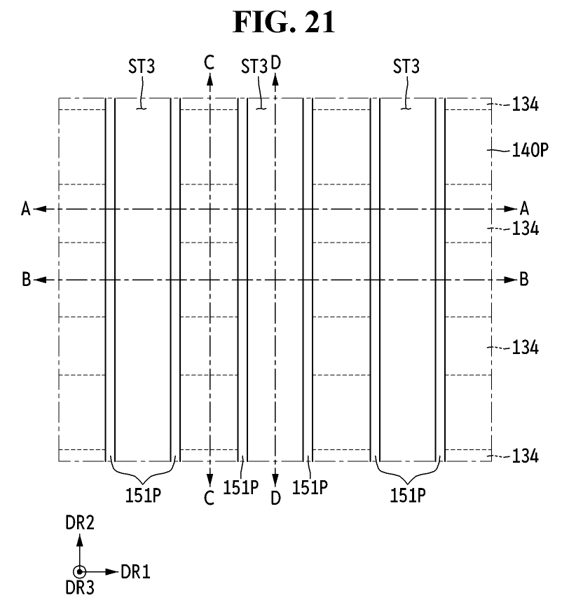

Referring to FIGS. 21-23, a third isolation trench ST3 may be formed in the first trench T1. A portion of the preliminary barrier insulating film 151P on the bottom surface of the first trench T1 and a portion of each of the sacrificial film 132 and the barrier conductive film 130 under the first trench T1 may be removed to form a third isolation trench ST3.

The third isolation trenches ST3 may extend in the second direction DR2 and may be spaced apart from each other in the first direction DR1. A width of the third isolation trench ST3 in the first direction DR1 may be smaller than a width of the first isolation pattern 121 and 123 in the first direction DR1 (a width of the first isolation trench ST1 in the first direction DR1). A bottom surface of the third isolation trench ST3 may be disposed in the first isolation pattern 121 and 123. The third isolation trench ST3 may expose the first isolation pattern 121 and 123. In addition, the third isolation trench ST3 may expose the sacrificial film 132.

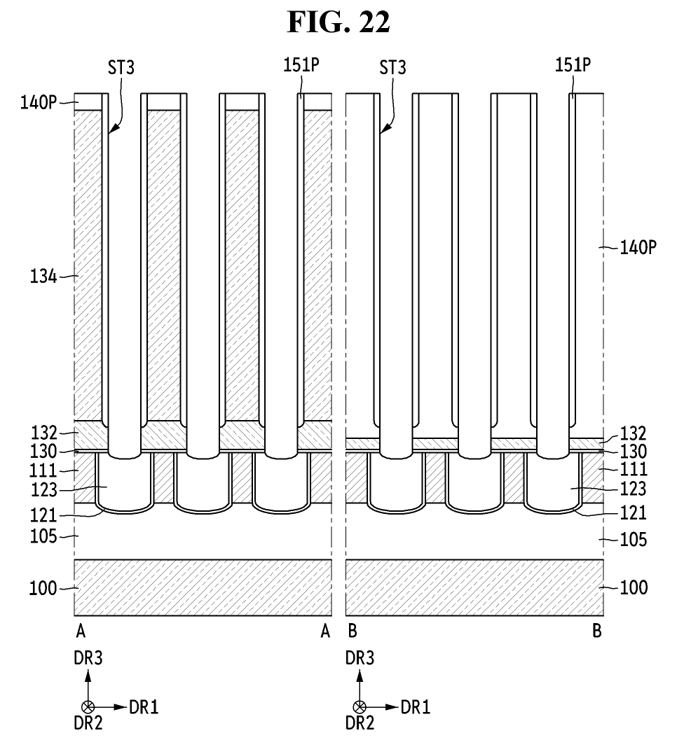

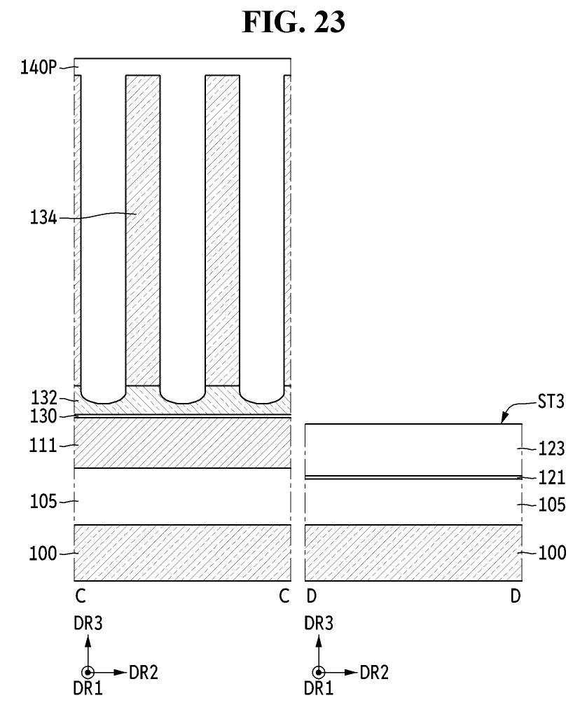

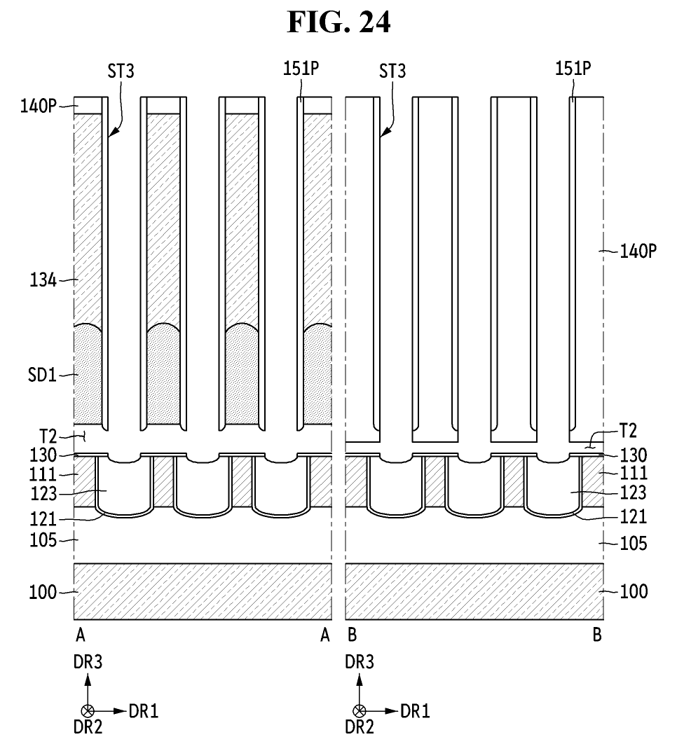

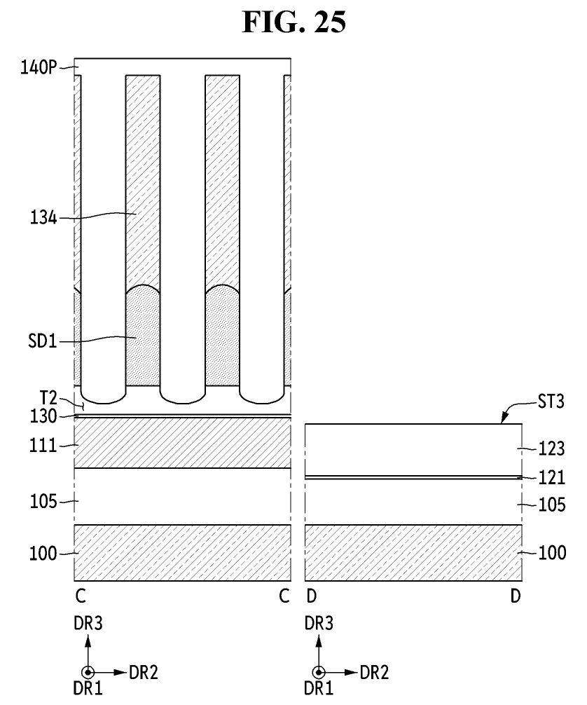

Referring to FIGS. 24 and 25, the sacrificial film 132 (see FIGS. 22 and 23) exposed through the third isolation trench ST3 may be removed to form a second trench T2. The second trench T2 may expose a lower surface of the active film 134. The second trench T2 may expose the barrier conductive film 130. The element isolation film as described with reference to FIGS. 13 and 14 may serve as a support in a process of removing the sacrificial film 132 (see FIGS. 22 and 23).

Subsequently, a portion of the active film 134 exposed through the second trench T2 may be doped with a dopant to form the first dopant area SD1. The first dopant area SD1 may be formed using a gas phase doping (GPD) process or a plasma doping (PLAD) process.

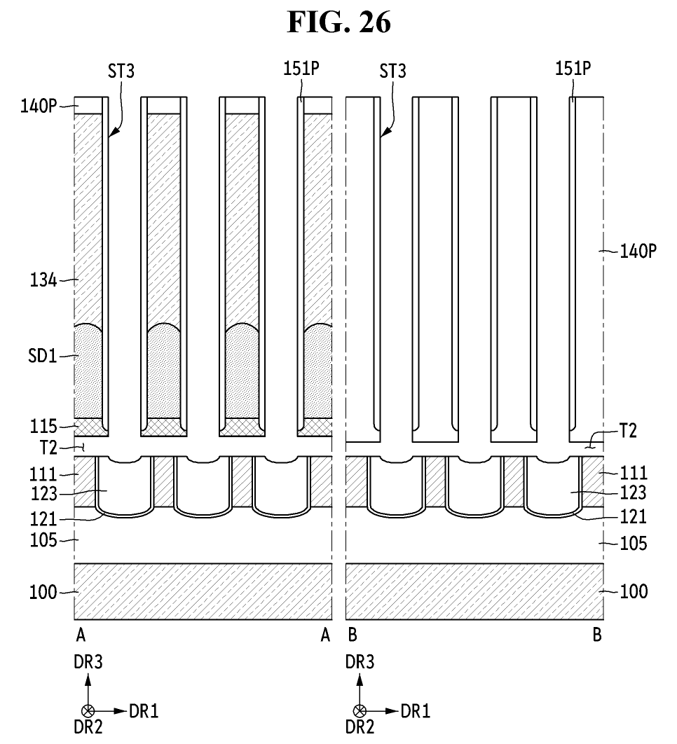

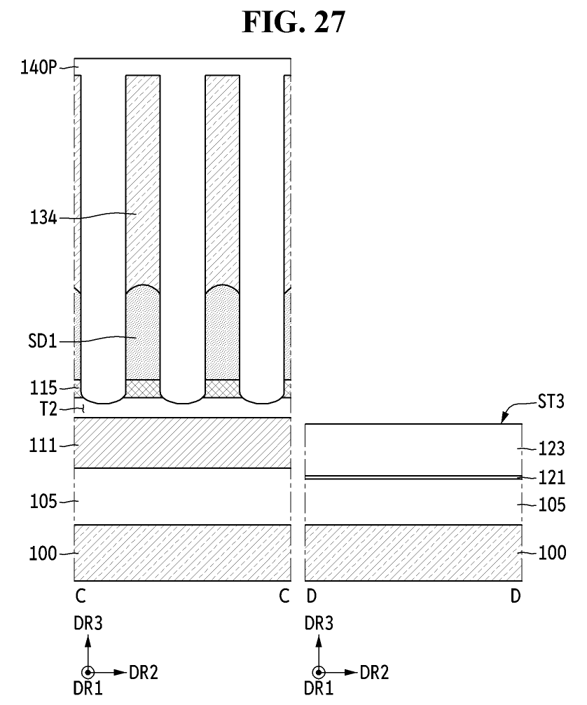

Referring to FIGS. 26 and 27, the metal silicide pattern 115 may be formed on a lower surface of the active film 134.

For example, a metal film may be formed on a lower surface of the active film 134, a capping layer may be formed on the metal film, a heat treatment process may be performed thereon, and then an unreacted portion of the metal film and the capping layer may be removed to form the metal silicide pattern 115. The metal film may include, for example, cobalt, nickel, titanium, and the like, and thus the metal silicide pattern 115 may include cobalt silicide, nickel silicide, titanium silicide, and the like. The heat treatment process may be, for example, a Rapid Thermal Silicide (RTS) process.

The barrier conductive film 130 exposed through the second trench T2 may be removed. Accordingly, the first conductive pattern 111 may be exposed, and the second trench T2 may be extended.

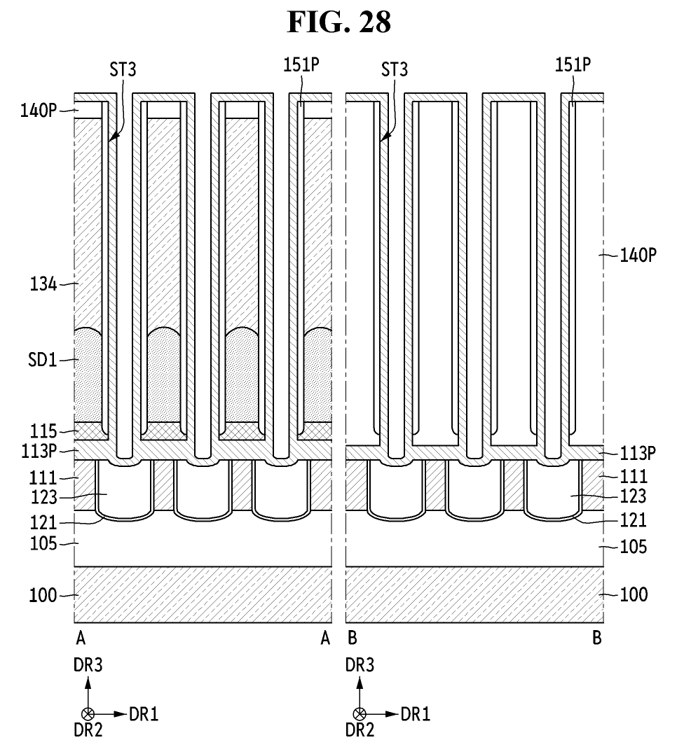

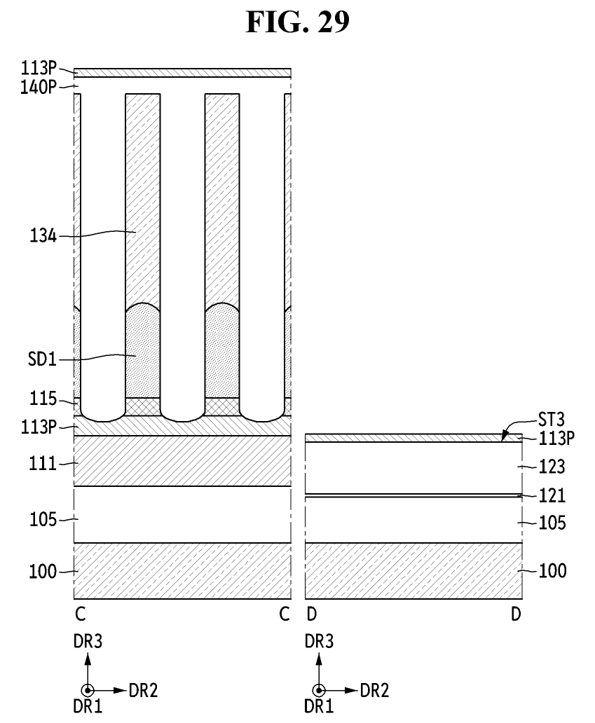

Referring to FIGS. 28 and 29, a preliminary conductive film 113P may be formed along sidewalls and a bottom surface of the third isolation trench ST3 to fill the second trench T2 (see FIGS. 26 and 27). The preliminary conductive film 113P may be formed along the upper surface of the first isolation pattern 121 and 123. The preliminary conductive film 113P may be formed along the upper surface of the preliminary isolation film 140P and the upper surface of the preliminary barrier insulating film 151P.

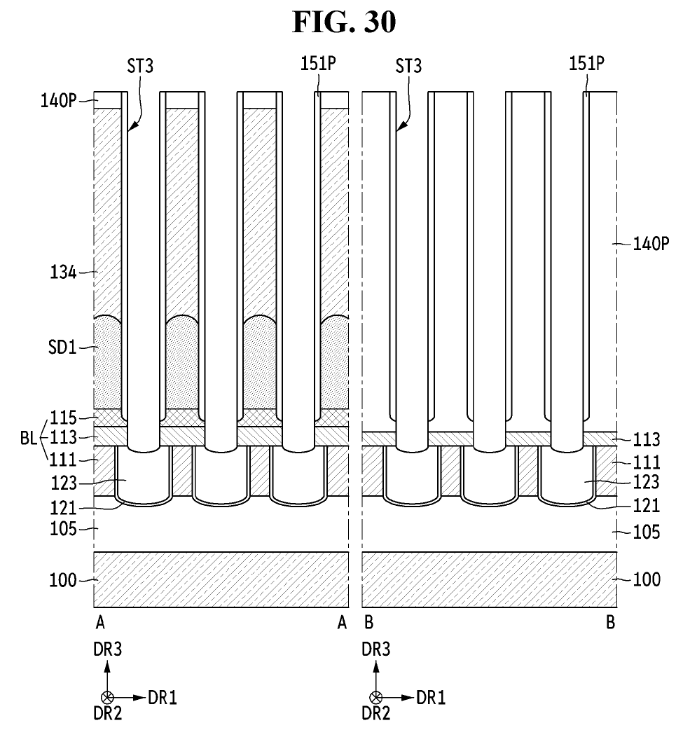

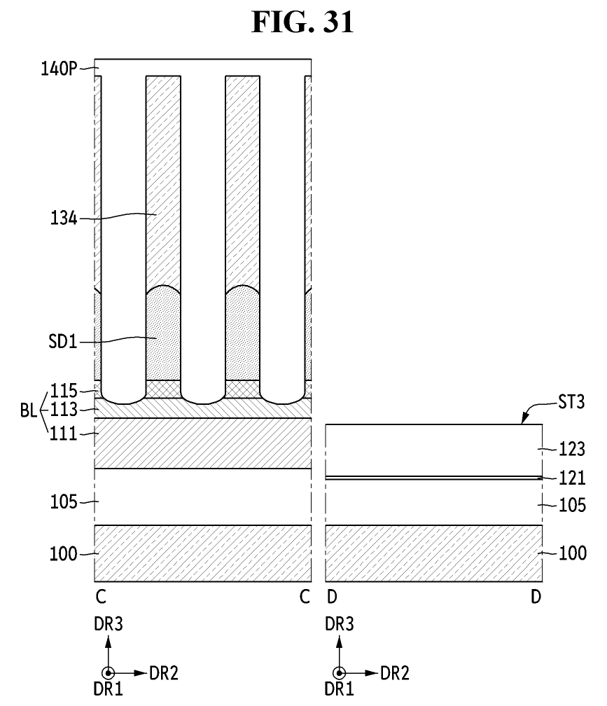

Referring to FIGS. 30 and 31, a portion of the preliminary conductive film 113P on the sidewall and the bottom surface of the third isolation trench ST3, the upper surface of the preliminary isolation film 140P, and the upper surface of the preliminary barrier insulating film 151P may be removed. Accordingly, the second conductive pattern 113 may be formed so as to fill the second trench T2, and the bit line BL including the first conductive pattern 111, the second conductive pattern 113, and the metal silicide pattern 115 may be formed. In addition, the third isolation trench ST3 may be formed again.

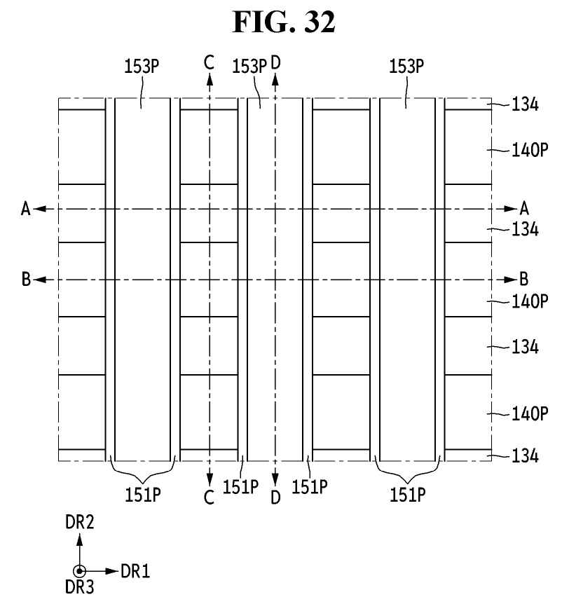

Referring to FIGS. 32-34, a preliminary isolation film 153P may be formed so as to fill the third isolation trench ST3 and cover the upper surface of the active film 134. A planarization process may be performed on the preliminary isolation film 153P. In the planarization process, a portion of the preliminary isolation film 140P and a portion of the preliminary barrier insulating film 151P on the upper surface of the active film 134 may be removed together.

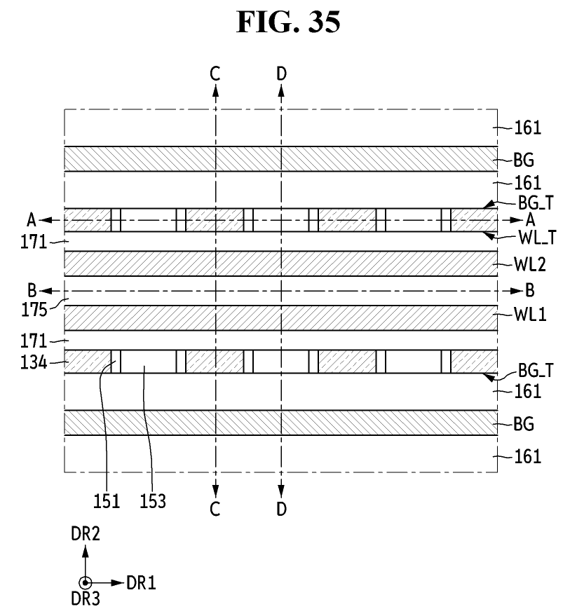

Referring to FIGS. 35-37, a back gate trench BG_T extending in the first direction DR1 and a word line trench WL_T extending in the first direction DR1 may be formed. The back gate trench BG_T and the word line trench WL_T may be formed on the preliminary isolation film 140P, the preliminary barrier insulating film 151P, and the preliminary isolation film 153P. Due to the formation of the back gate trench BG_T and the word line trench WL_T, the preliminary isolation film 140P, the preliminary barrier insulating film 151P, and the preliminary isolation film 153P may be partially etched, and the remaining preliminary isolation film 140P, the remaining preliminary barrier insulating film 151P, and the remaining preliminary isolation film 153P may act as the second isolation pattern 140, the barrier insulating pattern 151, and the third isolation pattern 153, respectively.

The back gate trench BG_T may be formed between the portions of the active film 134 adjacent to each other in the second direction DR2. The word line trench WL_T may be formed between the portions of the active film 134 adjacent to each other in the second direction DR2. The back gate trenches BG_T and the word line trenches WL_T may be alternately arranged with each other in the second direction DR2. A width of the back gate trench BG_T in the second direction DR2 may be smaller than a width of the word line trench WL_T in the second direction DR2. A vertical level of the bottom surface of the back gate trench BG_T may be lower than a vertical level of the bottom surface of the word line trench WL_T based on the bit line BL.

The back gate insulating pattern 161, the back gate electrode BG, and the back gate capping pattern 163 may be formed in the back gate trench BG_T. The back gate insulating pattern 161 may be formed along sidewalls and a bottom surface of the back gate trench BG_T. The back gate electrode BG may be formed on the back gate insulating pattern 161. The back gate electrode BG may fill a portion of the back gate trench BG_T. The back gate capping pattern 163 may be formed on the back gate electrode BG. The back gate capping pattern 163 may fill the remainder of the back gate trench BG_T.

The gate insulating pattern 171, the first and second word lines WL1 and WL2, the gate capping pattern 173, and the gate isolation pattern 175 may be formed in the word line trench WL_T. The gate insulating pattern 171 may be formed along sidewalls and a bottom surface of the word line trench WL_T. The first word line WL1 and the second word line WL2 may be formed on the gate insulating pattern 171 so as to be spaced apart from each other in the second direction DR2. The gate capping pattern 173 may be formed on the upper surface of the first word line WL1 and the upper surface of the second word line WL2. The gate isolation pattern 175 may fill a portion of the word line trench WL_T disposed between the first word line WL1 and the second word line WL2 and between the gate capping patterns 173 adjacent to each other in the second direction DR2.

Next, referring to FIGS. 1-3, a dopant may be doped into an upper surface of the active film 134 to form the second dopant area SD2. The second dopant area SD2 may be formed using a vapor phase doping (GPD) process or a plasma doping (PLAD) process. Accordingly, the active pattern AP1 and AP2 including the first and second dopant areas SD1 and SD2 and the channel area CH may be formed. The first active patterns AP1 may be formed to be spaced apart from each other in the first direction DR1 while being disposed between the back gate electrode BG and the first word line WL1 which are adjacent to each other in the second direction DR2. The second active patterns AP2 may be formed so as to be spaced apart from each other in the first direction DR1 while being disposed between the back gate electrode BG and the second word line WL2 adjacent to each other in the second direction DR2.

A contact hole exposing the first and second active pattern AP1 and AP2 may be formed in the first interlayer insulating film 185. The contact pattern BC and the contact silicide pattern 180 may be formed in the contact hole.

Subsequently, the data storage patterns DSP may be formed on the contact silicide pattern 180. The second interlayer insulating film 197 may be formed to cover the data storage patterns DSP.

In the method for manufacturing the semiconductor device according to some embodiments, the bit line BL, the back gate electrode BG, the word line WL1 and WL2, the active pattern AP1 and AP2, and the data storage pattern DSP are formed on the front surface of the substrate 100. Accordingly, the substrate 100 is not limited to a silicon-on-insulator substrate (i.e., a SOI substrate), and may be various substrates such as a silicon substrate and a glass substrate.

In the method for manufacturing the semiconductor device according to some embodiments, the data storage pattern DSP is formed after the first and second dopant areas SD1 and SD2 are formed. Accordingly, when the first and second dopant areas SD1 and SD2 are formed, deterioration of the data storage pattern DSP due to heat may be prevented, and a temperature at which the first and second dopant areas SD1 and SD2 are formed may not be limited due to deterioration of the data storage pattern DSP.

In the method for manufacturing the semiconductor device according to some embodiments, the preliminary conductive film is formed and the preliminary conductive film is patterned to form the first conductive pattern 111. In this regard, the preliminary conductive film may be formed using physical vapor deposition (PVD), and thus, the first conductive pattern 111 having a relatively low resistance may be formed.

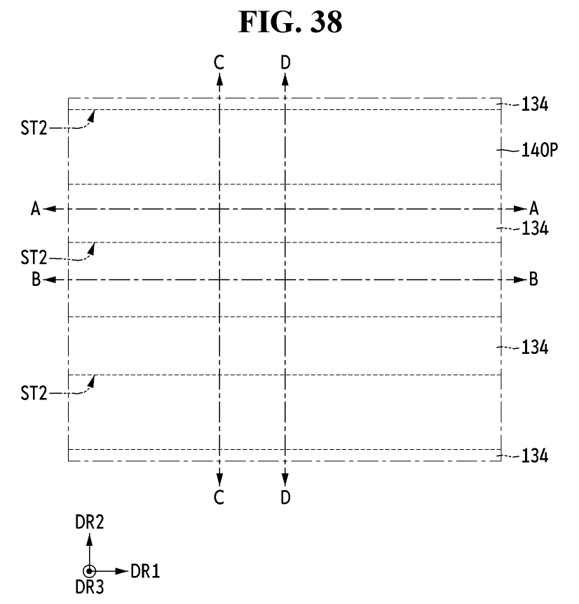

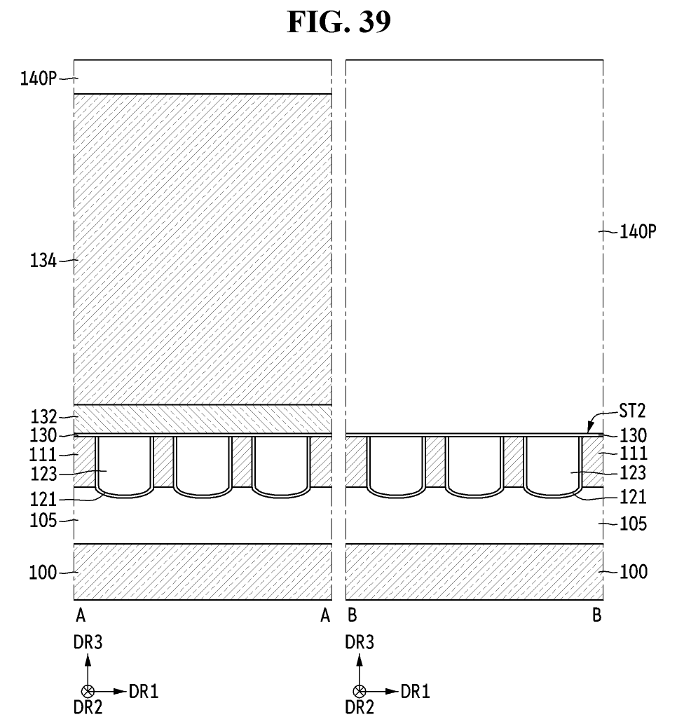

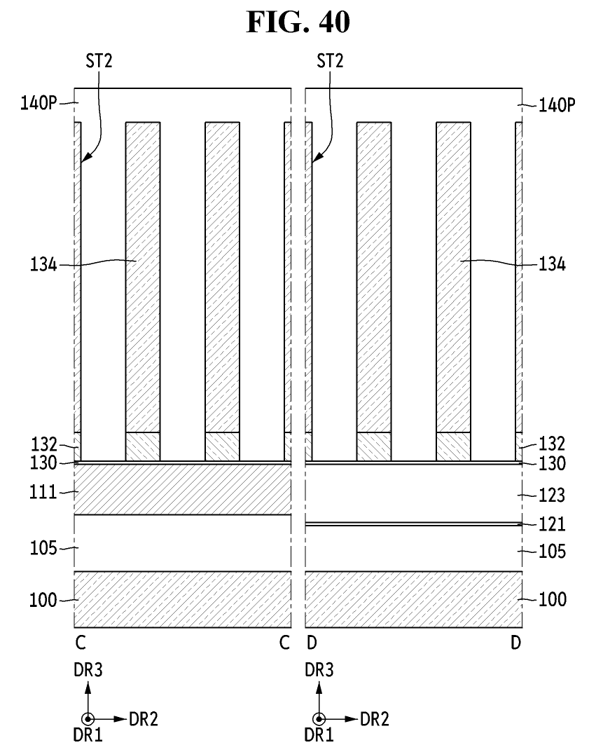

FIGS. 38-45 are diagrams illustrating a method for manufacturing a semiconductor device according to some embodiments. For reference, FIGS. 38-40 may be a manufacturing process as performed after FIGS. 13 and 14. For convenience of description, differences from those described above with reference to FIGS. 1-37 will be mainly described.

Referring to FIGS. 38-40, the second isolation trenches ST2 extending in the first direction DR1 and spaced apart from each other in the second direction DR2 may be formed. The portions of the active film 134 may be spaced apart from each other in the second direction DR2 due to the formation of the second isolation trench ST2 and may extend in the first direction DR1. The portions of the sacrificial film 132 may be spaced apart from each other in the second direction DR2 due to the formation of the second isolation trench ST2 and may extend in the first direction DR1.

In some embodiments, the bottom surface of the second isolation trench ST2 may be in contact with the barrier conductive film 130. In the process of forming the second isolation trench ST2, the barrier conductive film 130 may be used as an etch stop film.

Subsequently, the preliminary isolation film 140P filling the second isolation trench ST2 and covering the active film 134 may be formed. A planarization process may be performed on the preliminary isolation film 140P. The preliminary isolation film 140P may be in contact with the barrier conductive film 130.

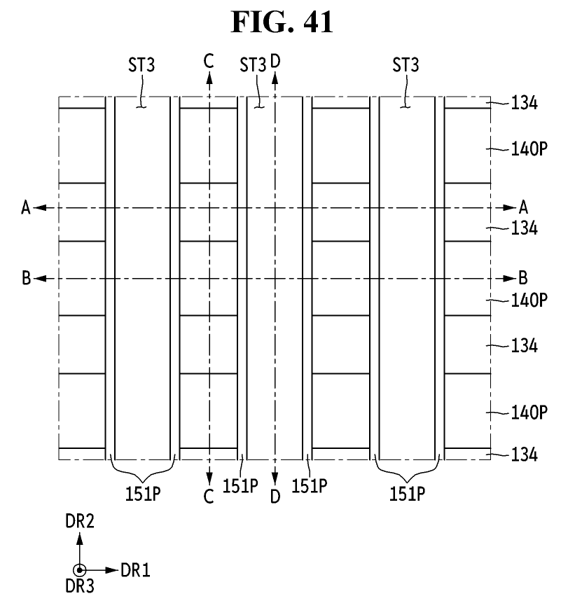

Referring to FIGS. 41-43, the first trenches T1 extending in the second direction DR2 and spaced apart from each other in the first direction DR1 may be formed in the sacrificial film 132, the active film 134, and the preliminary isolation film 140P. Subsequently, the preliminary barrier insulating film 151P may be formed along the bottom surface and sidewalls of the first trench T1. Subsequently, the third isolation trench ST3 may be formed in the first trench T1.

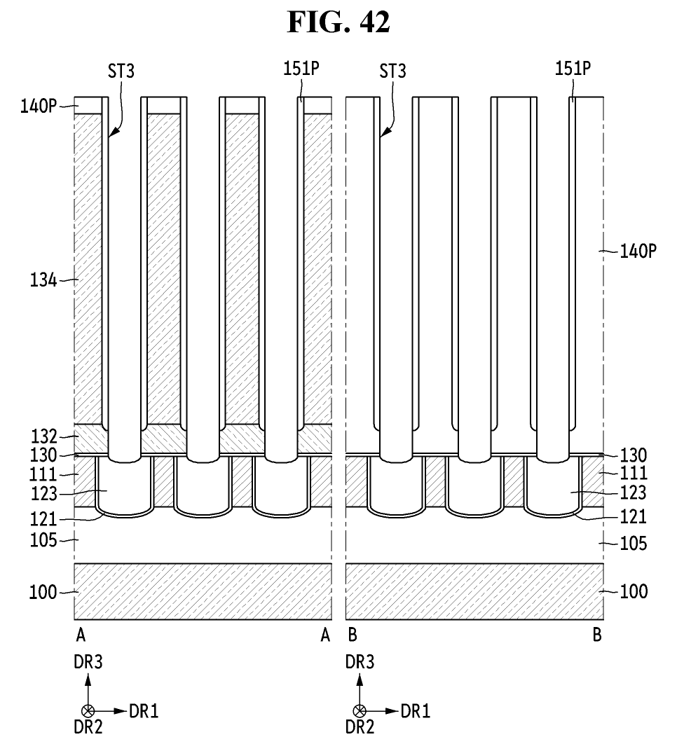

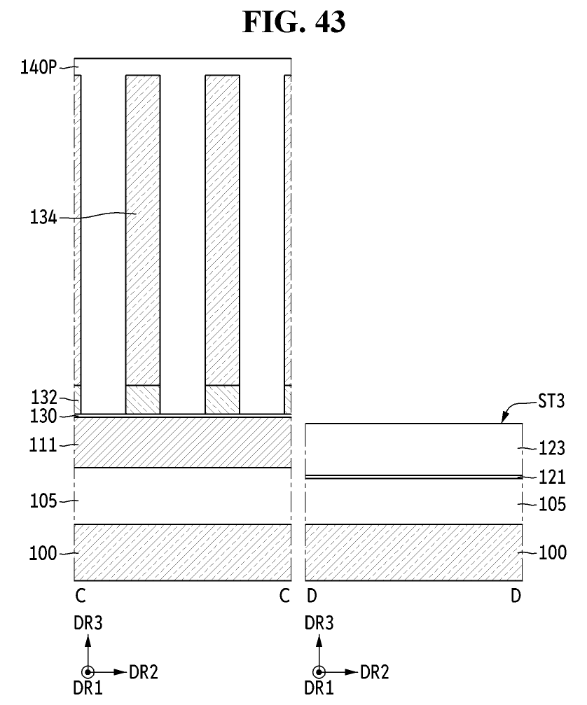

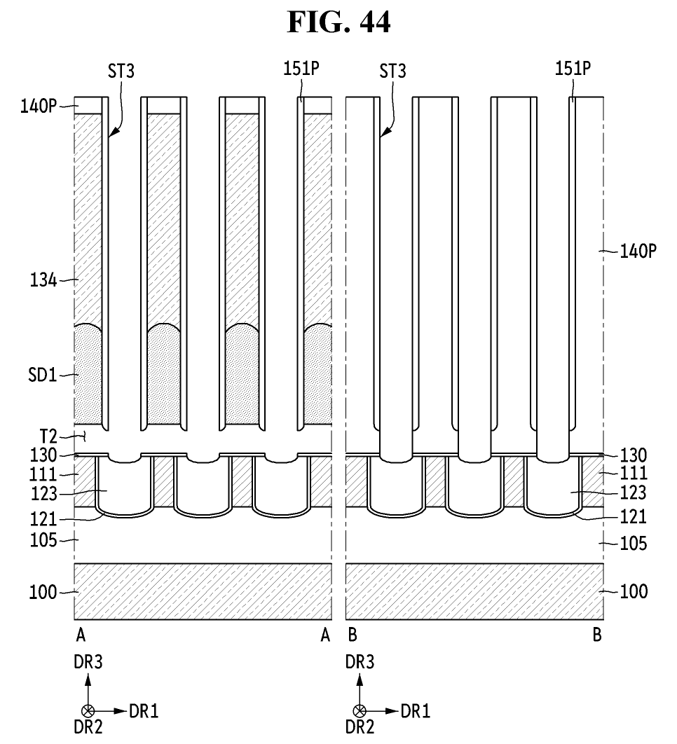

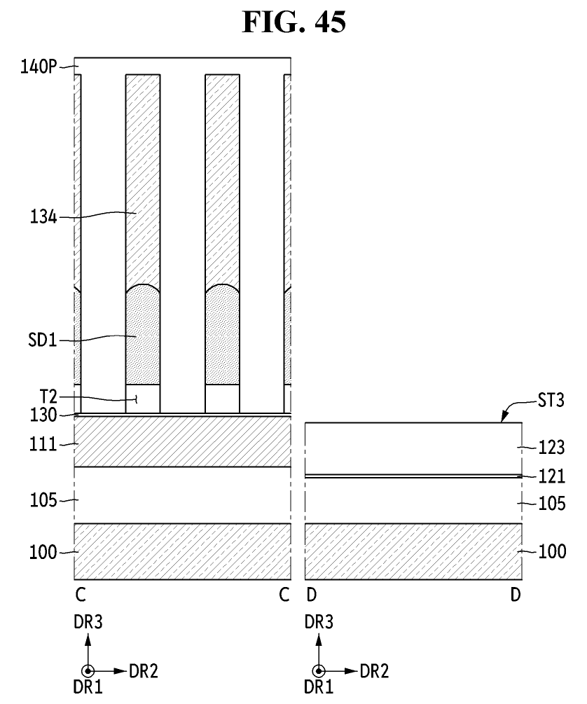

Referring to FIGS. 44 and 45, the sacrificial film 132 (see FIGS. 42 and 43) exposed through the third isolation trench ST3 may be removed to form a second trench T2. The second trench T2 may expose a lower surface of the active film 134. The second trench T2 may expose the barrier conductive film 130. The preliminary isolation film 140P in contact with the barrier conductive film 130 may serve as a support in a process of removing the sacrificial film 132 (see FIGS. 42 and 43).

Subsequently, the manufacturing method as described with reference to FIGS. 26-37 may be performed. In this way, the semiconductor device as described with reference to FIGS. 1-3 may be manufactured.

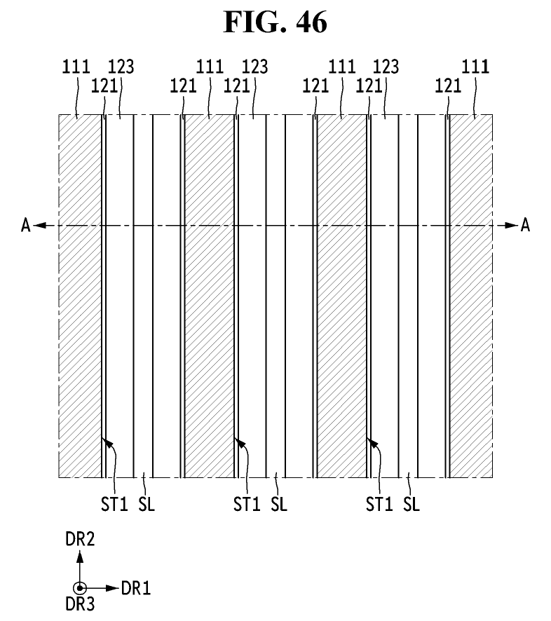

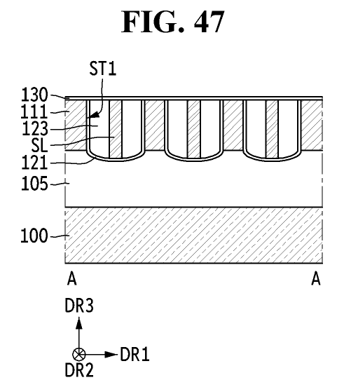

FIGS. 46 and 47 are diagrams illustrating a method for manufacturing a semiconductor device according to some embodiments. For convenience of description, differences from those described above with reference to FIGS. 1-45 will be mainly described.

Referring to FIGS. 46 and 47, the first conductive pattern 111, the first isolation pattern 121 and 123, and the shielding conductive pattern SL may be formed on the insulating film 105. A method for forming the insulating film 105 and the first conductive pattern 111 may be the same as described above with reference to FIGS. 11 and 12.

The first isolation pattern 121 and 123 and the shielding conductive pattern SL may be formed in the first isolation trench ST1. The first film 121 may be formed along sidewalls and a bottom surface of the first isolation trench ST1. The second film 123 and the shielding conductive pattern SL may be formed on the first film 121. The second film 123 and the shielding conductive pattern SL may fill the first isolation trench ST1. The shielding conductive pattern SL may be formed between the first conductive patterns 111 adjacent to each other in the first direction DR1. The second film 123 may fill a space between the shielding conductive pattern SL and the first conductive pattern 111. The order of the process of forming the shielding conductive pattern SL and the process of forming the second film 123 may be variously changed.

Subsequently, the barrier conductive film 130 may be formed on the first isolation pattern 121 and 123, the first conductive pattern 111, and the shielding conductive pattern SL. The barrier conductive film 130 may extend along the upper surfaces of the first isolation pattern 121 and 123, the upper surface of the first conductive pattern 111, and the upper surface of the shielding conductive pattern SL.

Subsequently, the manufacturing method as described with reference to FIGS. 13-45 may be performed. In this way, the semiconductor device described above with reference to FIGS. 4 and 5 may be manufactured.

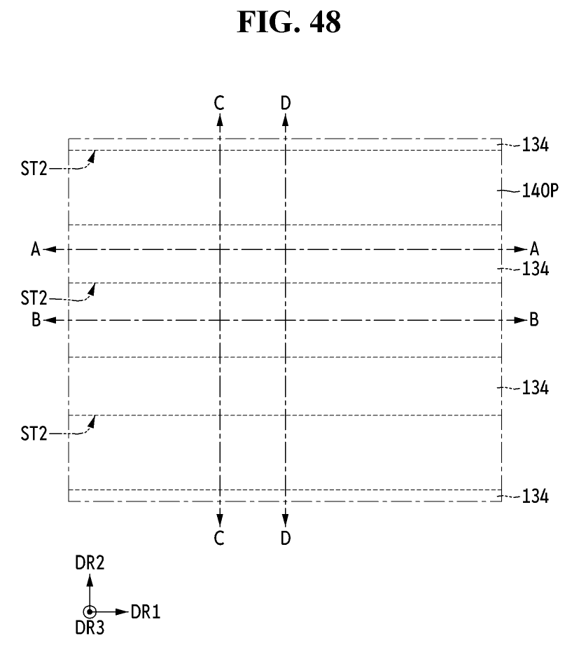

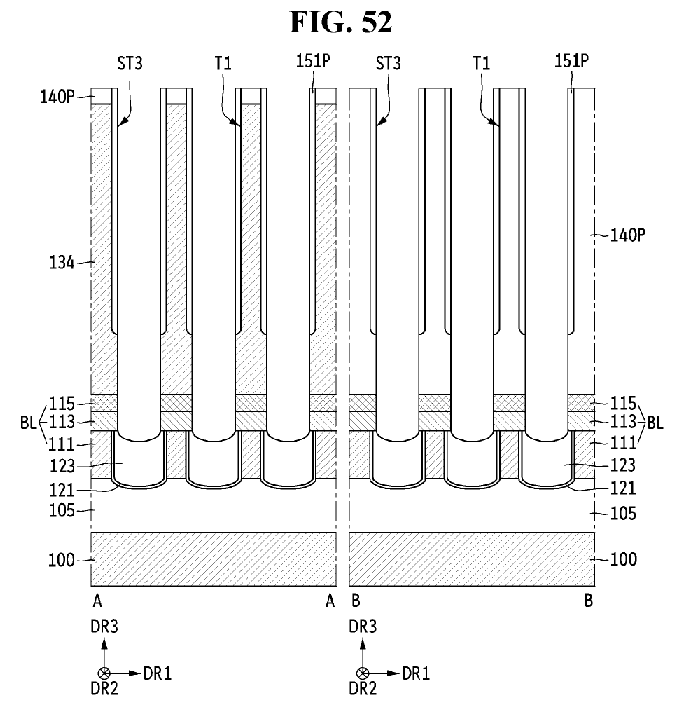

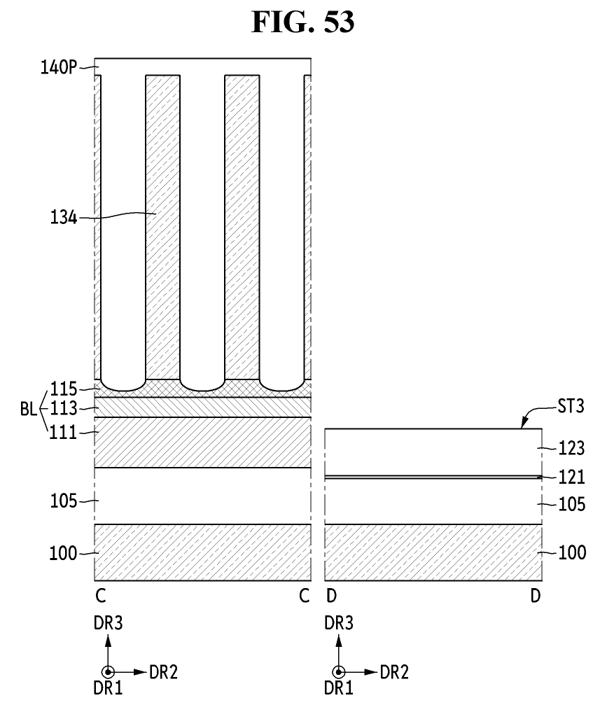

FIGS. 48-53 are diagrams illustrating a method for manufacturing a semiconductor device according to some embodiments. For convenience of description, differences from those described above with reference to FIGS. 1-47 will be mainly described.

Referring to FIGS. 48-50, the first conductive pattern 111 and the first isolation pattern 121 and 123 may be formed on the substrate 100. A second preliminary conductive film 113P may be formed on the first conductive pattern 111 and the first isolation pattern 121 and 123.

Subsequently, the active film 134 may be formed on the second preliminary conductive film 113P. In some embodiments, after the amorphous silicon layer is formed, an annealing process and/or a metal induced crystallization process may be performed thereon to form the active film 134 that is made of single crystalline silicon.

A preliminary metal silicide film 115P may be formed between the second preliminary conductive film 113P and the active film 134. In some embodiments, the preliminary metal silicide film 115P may be formed along the second preliminary conductive film 113P. The preliminary metal silicide film 115P may be formed on the entire upper surface of the second preliminary conductive film 113P.

Subsequently, the second isolation trenches ST2 extending in the first direction DR1 and spaced apart from each other in the second direction DR2 may be formed in the active film 134 and the preliminary metal silicide film 115P. A bottom surface of the second isolation trench ST2 may be disposed in the preliminary metal silicide film 115P. In the process of forming the second isolation trench ST2, the preliminary metal silicide film 115P may be used as an etch stop film.

Subsequently, the preliminary isolation film 140P filling the second isolation trench ST2 and covering the active film 134 may be formed. A planarization process may be performed on the preliminary isolation film 140P.

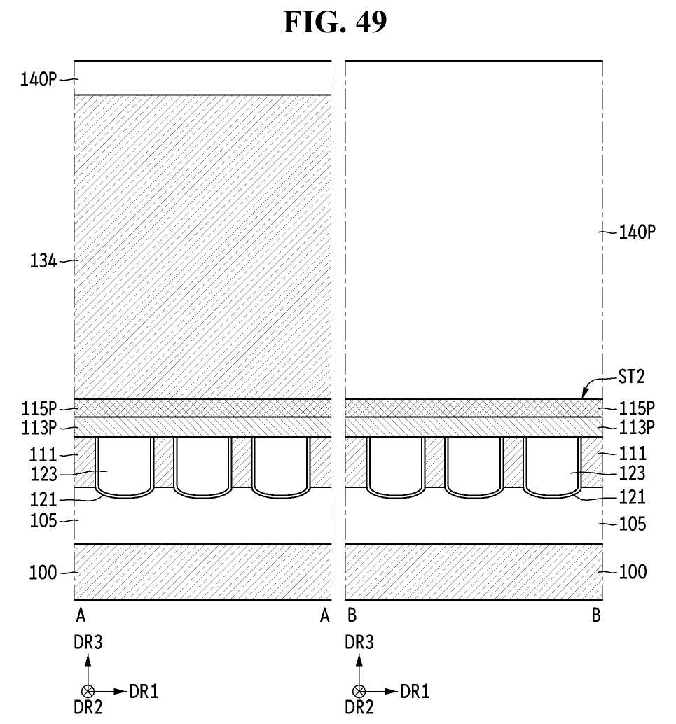

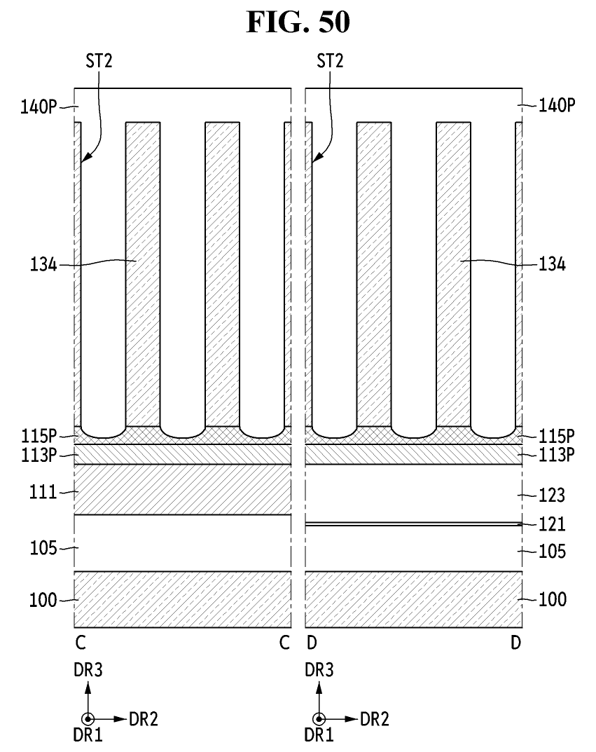

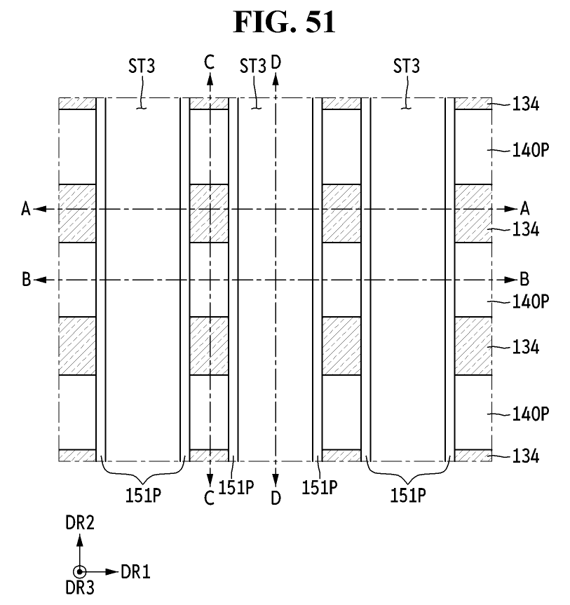

Referring to FIGS. 51-53, the first trenches T1 extending in the second direction DR2 and spaced apart from each other in the first direction DR1 may be formed in the preliminary isolation film 140P and the active film 134. The first trench T1 may intersect the second isolation trench ST2. A bottom surface of the first trench T1 may be disposed in the preliminary isolation film 140P and the active film 134. A vertical level of the bottom surface of the first trench T1 may be higher than a vertical level of the upper surface of the preliminary metal silicide film 115P (see FIGS. 49 and 50) based on the front surface of the substrate 100 on which the first conductive pattern 111 has been formed. The bottom surface of the first trench T1 may be spaced apart from the preliminary metal silicide film 115P (see FIGS. 49 and 50).

Subsequently, the preliminary barrier insulating film 151P may be formed along the bottom surface and sidewalls of the first trench T1. The active film 134 may include a first sidewall and a second sidewall opposite to each other in the first direction DR1, and the preliminary barrier insulating film 151P may extend along an upper portion of the first sidewall and an upper portion of the second sidewall of the active film 134. Accordingly, a width of an upper portion of the active film 134 in the first direction DR1 may be smaller than a width of a lower portion of the active film 134 in the first direction DR1.

Subsequently, the third isolation trench ST3 may be formed in the first trench T1. A portion of the preliminary barrier insulating film 151P on the bottom surface of the first trench T1, and a portion of each of the preliminary metal silicide film 115P (see FIGS. 49 and 50) and the second preliminary conductive film 113P (see FIGS. 49 and 50) under the first trench T1 may be removed to form the third isolation trench ST3. A portion of the preliminary metal silicide layer 115P (see FIGS. 49 and 50) may be removed via the formation of the third isolation trench ST3, thereby forming the metal silicide pattern 115. A portion of the second preliminary conductive film 113P (see FIGS. 49 and 50) may be removed via the formation of the third isolation trench ST3 to form the second conductive pattern 113. In this way, the bit line BL including the first conductive pattern 111, the second conductive pattern 113, and the metal silicide pattern 115 may be formed.

Next, referring to FIGS. 51-53, and FIGS. 6 and 7, a portion of the active film 134 exposed through the third isolation trench ST3 may be doped with a dopant to form the first dopant area SD1.

Subsequently, a third isolation pattern 153 may be formed to fill the third isolation trench ST3. For example, a preliminary isolation film may be formed to fill the third isolation trench ST3 and cover the upper surface of the active film 134, and a planarization process may be performed on the preliminary isolation film to form the third isolation pattern 153. In the planarization process, a portion of the preliminary isolation film 140P and a portion of the preliminary barrier insulating film 151P on the upper surface of the active film 134 may be removed together, and thus, the second isolation pattern 140 and the barrier insulating pattern 151 may be formed.

Subsequently, the back gate insulating pattern 161, the back gate electrode BG, the back gate capping pattern 163, the gate insulating pattern 171, the first and second word lines WL1 and WL2, the gate capping pattern 173, and the gate isolation pattern 175 may be formed.

A dopant may be doped into the upper surface of the active film 134 to form the second dopant area SD2. Accordingly, the active pattern AP1 and AP2 including the first and second dopant areas SD1 and SD2 and the channel area CH may be formed.

Subsequently, the first interlayer insulating film 185, the contact pattern BC, the contact silicide pattern 180, the data storage patterns DSP, and the second interlayer insulating film 197 may be formed.

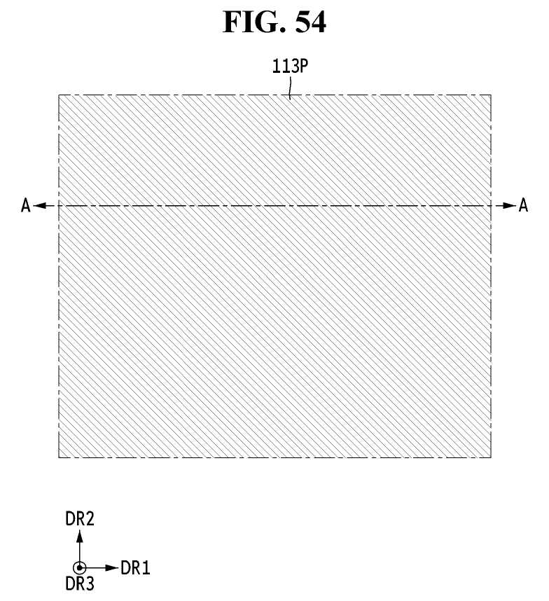

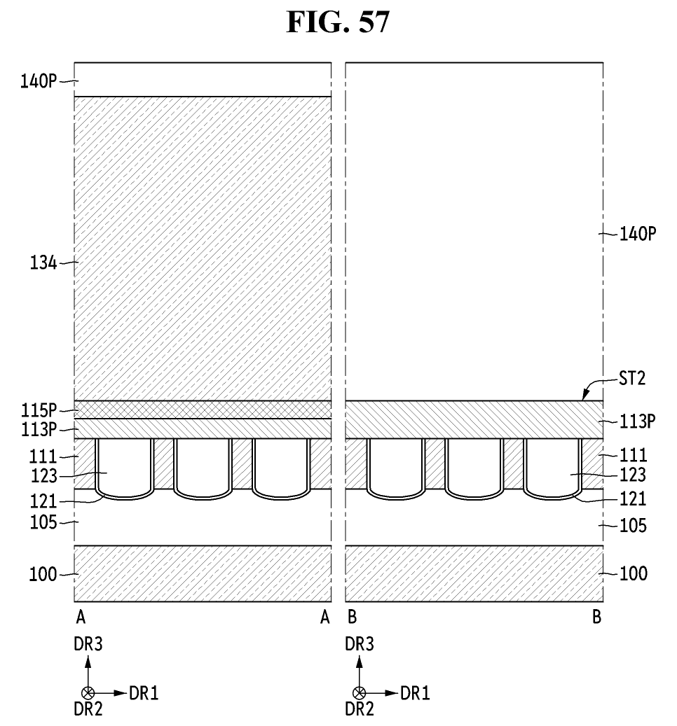

FIGS. 54-58 are diagrams illustrating a method for manufacturing a semiconductor device according to some embodiments. For convenience of description, differences from those described above with reference to FIGS. 1-53 will be mainly described.

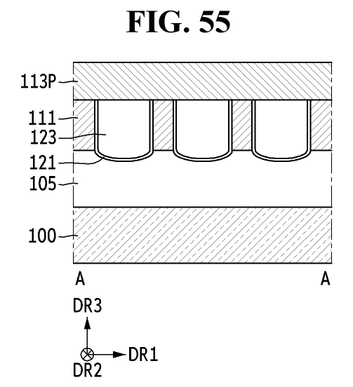

Referring to FIGS. 54 and 55, the first conductive pattern 111 and the first isolation pattern 121 and 123 may be formed on the substrate 100. The second preliminary conductive film 113P may be formed on the first conductive pattern 111 and the first isolation pattern 121 and 123.

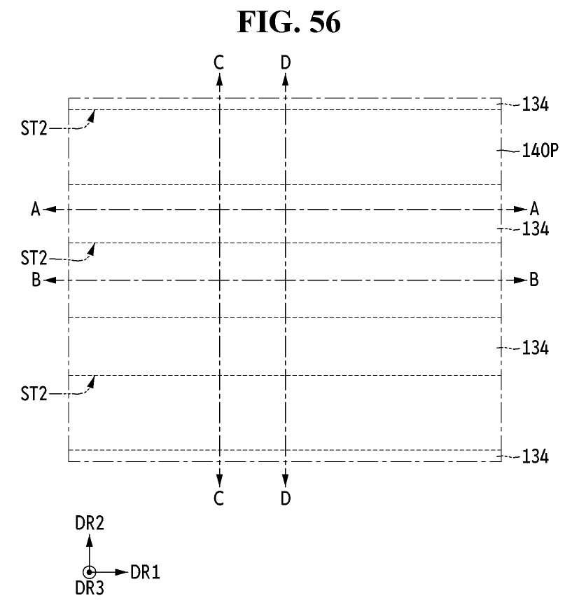

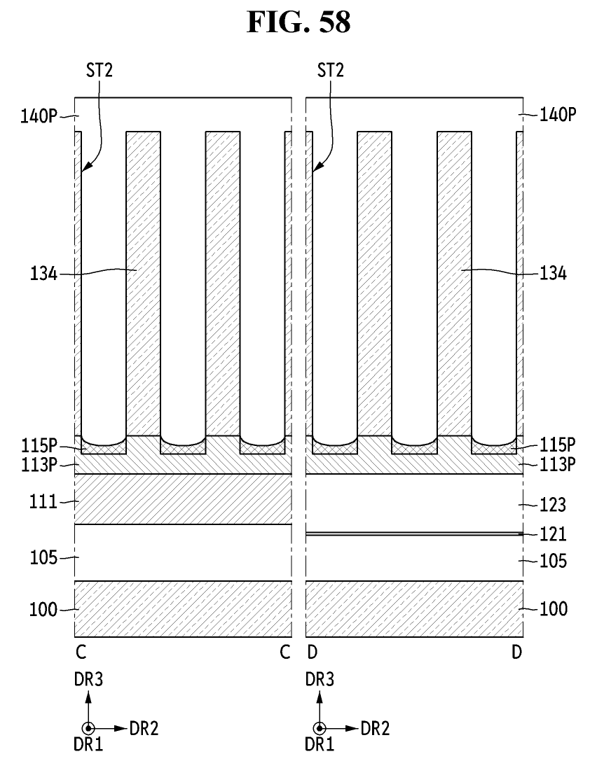

Referring to FIGS. 56 and 58, the active film 134 may be formed on the second preliminary conductive film 113P. In some embodiments, after the amorphous silicon layer is formed, an annealing process and/or a metal induced crystallization process may be performed thereon to form the active film 134 that is made of single crystalline silicon.

The second isolation trenches ST2 extending in the first direction DR1 and spaced apart from each other in the second direction DR2 may be formed in the active film 134 and the second preliminary conductive film 113P. Accordingly, the portions of the active film 134 may extend in the first direction DR1 and may be spaced apart from each other in the second direction DR2. A bottom surface of the second isolation trench ST2 may be disposed in the second preliminary conductive film 113P. In the process of forming the second isolation trench ST2, the second preliminary conductive film 113P may be used as an etch stop film.

The preliminary metal silicide film 115P may be formed between the second preliminary conductive film 113P and the active film 134. In some embodiments, the preliminary metal silicide film 115P may be formed along the active film 134. Portions of the preliminary metal silicide film 115P may extend in the first direction DR1 and may be spaced apart from each other in the second direction DR2.

Subsequently, the preliminary isolation film 140P filling the second isolation trench ST2 and covering the active film 134 may be formed. A planarization process may be performed on the preliminary isolation film 140P.

Subsequently, the manufacturing method as described above with reference to FIGS. 51-53 may be performed. In this way, the semiconductor device described above with reference to FIGS. 8 and 9 may be manufactured.

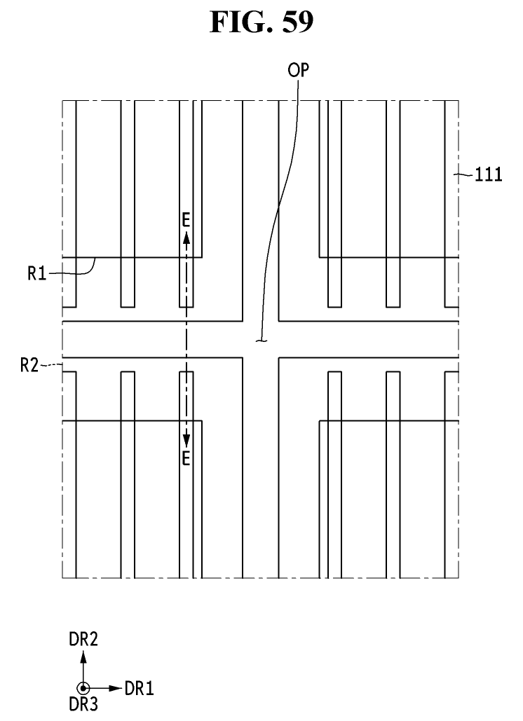

FIGS. 59-62 are diagrams illustrating a method for manufacturing a semiconductor device according to some embodiments. For convenience of description, differences from those described above with reference to FIGS. 1-53 will be mainly described.

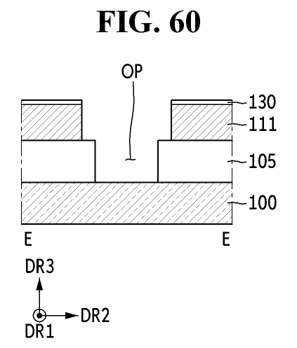

Referring to FIGS. 59-60, the substrate 100 may include a first area R1 and a second area R2. The first area R1 may be spaced apart from each other in each of the first direction DR1 and the second direction DR2. The second area R2 may be defined around the first area R1. The first area R1 may be referred to as a memory block area, and the second area R2 may be referred to as an interface area. Later, the memory cells may be formed on the first area R1. The substrate 100 may include silicon or silicon germanium.

As described above with reference to FIGS. 11 and 12, the insulating film 105, the first conductive pattern 111, and the first isolation pattern 121 and 123 may be formed on the substrate 100. An end of the first conductive pattern 111 in the second direction DR2 and an end of the first isolation pattern 121 and 123 in the second direction DR2 may be disposed on the second area R2.

Subsequently, an opening OP may be formed in the second area R2. The opening OP may extend through the insulating film 105 so as to expose a portion of the substrate 100. In some embodiments, the opening OP may be provided in a form of a line. For example, the opening OP may include a first portion extending in the first direction DR1 and a second portion intersecting the first portion and extending in the second direction DR2. The opening OP may have a cross shape in a plan view. In some embodiments, the opening OP may be provided in a form of a contact. For example, the openings OP may be spaced apart from each other in the second direction DR2.

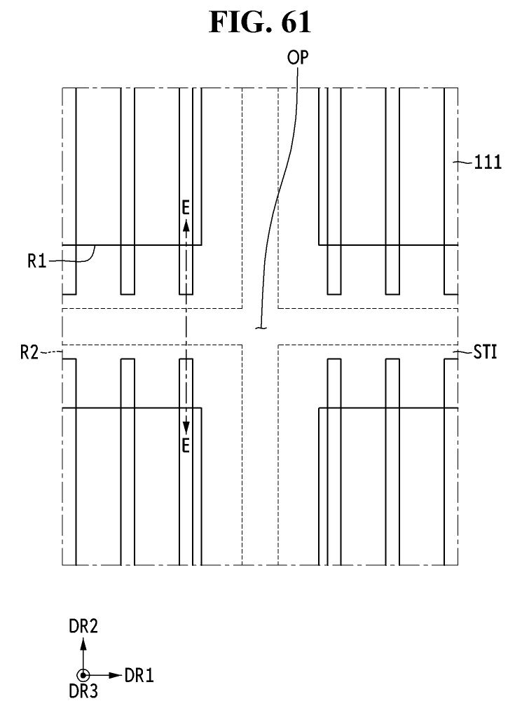

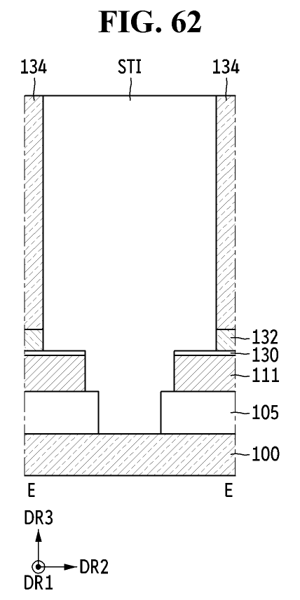

Referring to FIGS. 61 and 62, the sacrificial film 132 and the active film 134 may be formed in an epitaxial growth process using the exposed substrate 100 as a seed layer. The sacrificial film 132 and the active film 134 may fill the opening OP and a space between the first conductive patterns 111 adjacent to each other. The sacrificial film 132 and the active film 134 may be formed on the first area R1 and the second area R2. The sacrificial film 132 and the active film 134 may cover the first conductive pattern 111.

Subsequently, the sacrificial film 132 and the active film 134 may be patterned. An element isolation film STI may be formed in the sacrificial film 132 and the active film 134 on the second area R2. Portions of the sacrificial film 132 of different first areas R1 may be isolated from each other via the element isolation film STI. Portions of the active film 134 of different first areas R1 may be isolated from each other via the element isolation film STI. The element isolation film STI may fill the opening OP and a space between the adjacent first conductive patterns 111. The element isolation film STI is made of an insulating material. The element isolation film STI may serve as a support in a subsequent process of removing the sacrificial film 132.

Subsequently, the manufacturing method as described above with reference to FIGS. 15-37 may be performed. Thus, the semiconductor device described above with reference to FIGS. 1-3 may be manufactured in the first area R1 of the substrate 100.

Alternatively, subsequently, the manufacturing method as described above with reference to FIGS. 38-45 may be performed, and thus, the semiconductor device described above with reference to FIGS. 1-3 may be manufactured in the first area R1 of the substrate 100.

Alternatively, subsequently, the manufacturing method as described above with reference to FIGS. 48-53 may be performed, and thus, the semiconductor device as described above with reference to FIGS. 6 and 7 may be manufactured in the first area R1 of the substrate 100.

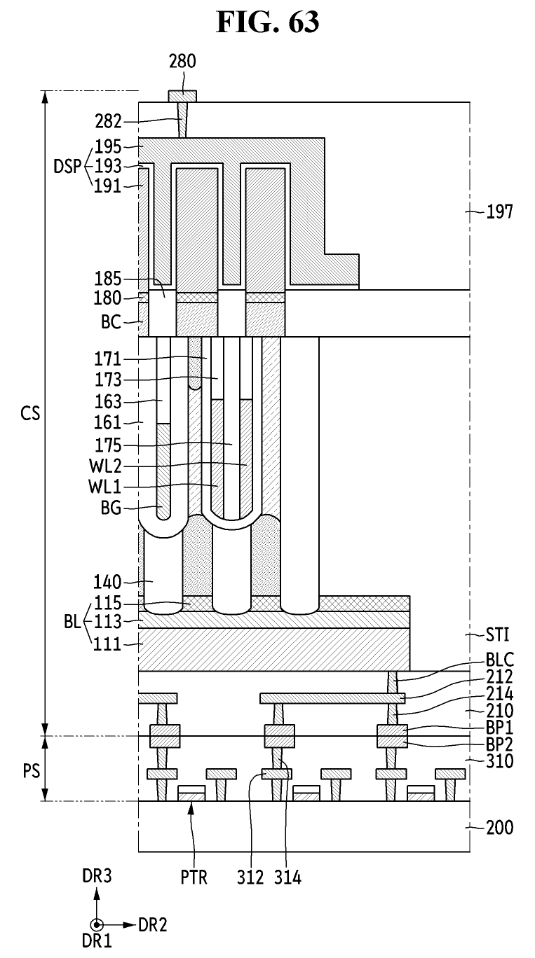

FIG. 63 is a cross-sectional view illustrating a semiconductor device according to some embodiments. For convenience of description, differences from those described above with reference to FIGS. 1-62 will be mainly described.

Referring to FIG. 63, the semiconductor device according to some embodiments may include a substrate 200, a cell structure CS, and a peripheral circuit structure PS.

The substrate 200 may be a silicon substrate, or may include a material other than silicon, for example, silicon germanium, indium antimonide, lead telluride compound, indium arsenide, indium phosphide, gallium arsenide, or gallium antimonide.

The cell structure CS and the peripheral circuit structure PS may be disposed on the substrate 200. The cell structure CS and the peripheral circuit structure PS may overlap each other in the third direction DR3. In some embodiments, the cell structure CS may be stacked on the peripheral circuit structure PS. The peripheral circuit structure PS may be disposed between the substrate 200 and the cell structure CS.

The cell structure CS includes the bit line BL, the word line WL1 and WL2, the back gate electrode BG, the active pattern AP1 and AP2, and the data storage pattern DSP, which have been described above with reference to FIGS. 1-10. The cell structure CS may further include the element isolation film STI, a connection pad 280, a connection pad plug 282, a cell interlayer insulating film 210, a bit line contact BLC, a cell connection line 212, and a cell connection via 214.

The element isolation film STI may cover an end portion of the bit line BL.

The connection pad 280 may be disposed on the second interlayer insulating film 197. The connection pad plug 282 may be disposed in the second interlayer insulating film 197. The connection pad plug 282 may connect the connection pad 280 to the data storage pattern DSP. Each of the connection pad 280 and the connection pad plug 282 may include at least one of conductive metal nitride, conductive metal silicon nitride, metal carbonitride, conductive metal oxide, or metal.

A cell interlayer insulating film 210 may be disposed on a bottom surface of the element isolation film STI and a bottom surface of the bit line BL. The bit line contact BLC, the cell connection line 212, and the cell connection via 214 may be disposed in the cell interlayer insulating film 210. The bit line contact BLC may connect the bit line BL and the cell connection line 212 to each other. Various contacts may be disposed in the cell interlayer insulating film 210. For example, a contact connected to the first and second word lines WL1 and WL2, a contact connected to the back gate electrode BG, etc. may be disposed in the cell interlayer insulating film 210.

The peripheral circuit structure PS may include a peripheral circuit transistor PTR, a peripheral interlayer insulating film 310, a peripheral connection line 312, and a peripheral connection via 314. The peripheral circuit transistor PTR may be disposed on the substrate 200. The peripheral circuit transistor PTR may be a sensing transistor, a transfer transistor, a driving transistor, or the like. The peripheral interlayer insulating film 310 may cover the peripheral circuit transistor PTR. The peripheral connection line 312 and the peripheral connection via 314 may be disposed in the peripheral interlayer insulating film 310. The peripheral connection line 312 and the peripheral connection via 314 may be connected to the peripheral circuit transistor PTR.

In some embodiments, the cell structure CS and the peripheral circuit structure PS may be bonded to each other via a C2C (Cu to Cu) wafer bonding scheme. The cell structure CS may further include a cell bonding pad BP1 connected to the cell connection line 212 in the cell interlayer insulating film 210. The peripheral circuit structure PS may further include a peripheral bonding pad BP2 connected to the peripheral connection line 312 in the peripheral interlayer insulating film 310. The cell bonding pad BP1 may be connected to the peripheral bonding pad BP2. The cell bonding pad BP1 may be in contact with the peripheral bonding pad BP2, and the cell interlayer insulating film 210 may be in contact with the peripheral interlayer insulating film 310. Accordingly, the cell structure CS and the peripheral circuit structure PS may be electrically connected to each other.

The substrate 200 may include a front surface on which the peripheral circuit transistor PTR is disposed, and a rear surface opposite to the front surface in the third direction DR3. For example, the front surface of the substrate 200 may face the cell structure CS. In another example, the rear surface of the substrate 200 may face the cell structure CS. For example, the bit line BL may face the front surface of the substrate 200. In still another example, the data storage pattern DSP may face the front surface of the substrate 200.

Each of the cell interlayer insulating film 210 and the peripheral interlayer insulating film 310 may be made of an insulating material. Each of the bit line contact BLC, the cell connection line 212, the cell connection via 214, the cell bonding pad BP1, the peripheral connection line 312, and the peripheral connection via 314 may include a conductive material including a metal.

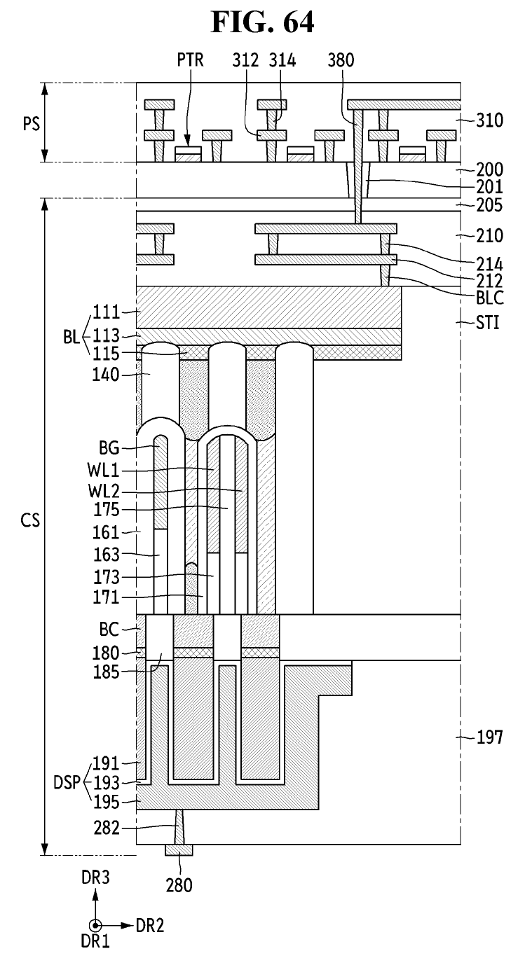

FIG. 64 is a cross-sectional view illustrating a semiconductor device according to some embodiments. For convenience of description, differences from those described above with reference to FIGS. 1-63 will be mainly described.

Referring to FIG. 64, in the semiconductor device according to some embodiments, the substrate 200 may be disposed between the cell structure CS and the peripheral circuit structure PS. The peripheral circuit structure PS may be disposed on the front surface of the substrate 200, and the cell structure CS may be disposed on the back surface of the substrate 200.

In some embodiments, the cell structure CS and the peripheral circuit structure PS may be connected to each other via a through via 380 in a direct bonding manner. The through via 380 may extend in the third direction DR3 so as to connect the peripheral circuit structure PS and the cell structure CS to each other.

For example, the cell structure CS may further include a buffer layer 205 on the rear surface of the substrate 200. The buffer layer 205 may be disposed between the substrate 200 and the cell interlayer insulating film 210. A spacer 201 may be disposed in the substrate 200. The buffer layer 205 and the spacer 201 may be made of an insulating material. The through via 380 may extend in the third direction DR3 so as to connect the cell connection line 212 and the peripheral connection line 312 to each other. The through via 380 may extend through the peripheral interlayer insulating film 310, the substrate 200, the buffer layer 205, and a portion of the cell interlayer insulating film 210. The through via 380 includes a conductive material.

In some embodiments, the peripheral circuit structure PS and the cell structure CS may be spaced apart from each other in the first direction DR1 or the second direction DR2 while being disposed on the substrate 200. For example, the substrate 200 may include a first area and a second area defined around the first area. The cell structure CS may be formed on the first area of the substrate 200, and the peripheral circuit structure PS may be formed on the second area of the substrate 200. The cell structure CS and the peripheral circuit structure PS may be electrically connected to each other via a line extending from the cell structure CS to the peripheral circuit structure PS.

According to the aforementioned and other embodiments of the present disclosure, there is provided a method for manufacturing a semiconductor device including forming a first conductive pattern on the substrate, wherein the first conductive pattern extends in a first direction; forming a sacrificial film and an active film on the first conductive pattern; forming a first isolation pattern in the sacrificial film and the active film, wherein the first isolation pattern extends in a second direction intersecting the first direction; forming an isolation trench in the sacrificial film, the active film, and the first isolation pattern, wherein the isolation trench extends in the first direction; removing a portion of the sacrificial film exposed through the isolation trench to form a trench; forming a metal silicide pattern on a portion of the active film exposed through the trench; forming a second conductive pattern on the metal silicide pattern so as to fill the trench; forming a second isolation pattern filling the isolation trench; and forming a word line extending in the first isolation pattern, the second isolation pattern, and the active film, wherein the word line extends in the second direction.

Although embodiments of the present disclosure have been described above with reference to the accompanying drawings, the present disclosure may not be limited to embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that embodiments as described above are not restrictive but illustrative in all respects.

What is claimed is:

1. A semiconductor device comprising:
a word line extending in a first direction;
a bit line extending in a second direction, wherein the bit line includes a first conductive pattern, a second conductive pattern disposed on the first conductive pattern, and a metal silicide pattern disposed on the second conductive pattern;
an active pattern including a first surface electrically connected to the bit line, and a second surface opposite to the first surface in a third direction; and
a data storage pattern electrically connected to the second surface of the active pattern,
wherein a width of the first conductive pattern in the first direction is different from a width of the second conductive pattern in the first direction.

2. The semiconductor device of claim 1, wherein the width of the first conductive pattern in the first direction is smaller than the width of the second conductive pattern in the first direction.

3. The semiconductor device of claim 1, wherein the word line includes a first portion having a first width in the second direction and a second portion having a second width in the second direction different from the first width.

4. The semiconductor device of claim 1, wherein the metal silicide pattern includes a third surface in contact with the second conductive pattern and a fourth surface in contact with the first surface of the active pattern,
wherein a width of the third surface in the first direction is greater than a width of the fourth surface in the first direction.

5. The semiconductor device of claim 1, wherein a width of the first surface of the active pattern in the second direction is greater than a width of the second surface of the active pattern in the second direction.

6. The semiconductor device of claim 1, wherein a width of the first surface of the active pattern in the first direction is greater than a width of the second surface of the active pattern in the first direction.

7. The semiconductor device of claim 1, wherein the metal silicide pattern extends in the second direction and along the second conductive pattern.

8. The semiconductor device of claim 1, wherein the bit line includes a plurality of metal silicide patterns, and the metal silicide patterns are spaced apart from each other on the second conductive pattern in the second direction.

9. The semiconductor device of claim 8, wherein a portion of the second conductive pattern is further disposed between the metal silicide patterns spaced apart from each other in the second direction.

10. The semiconductor device of claim 1, further comprising a shielding conductive pattern spaced apart from the bit line in the first direction.

11. The semiconductor device of claim 10, wherein an upper surface of the shielding conductive pattern is lower than an upper surface of the first conductive pattern in the third direction.

12. A semiconductor device comprising:
a word line extending in a first direction;
a bit line extending in a second direction, wherein the bit line includes a first sidewall and a second sidewall opposite to each other in the first direction;
an active pattern including a first surface electrically connected to the bit line and a second surface opposite to the first surface in a third direction; and
a data storage pattern electrically connected to the second surface of the active pattern,
wherein at least one of the first sidewall or the second sidewall of the bit line has a step defined by the first direction.

13. The semiconductor device of claim 12, wherein the active pattern includes a third sidewall and a fourth sidewall opposite to each other in the first direction,
wherein at least one of the third sidewall or the fourth sidewall of the active pattern has a step defined by the first direction.

14. The semiconductor device of claim 12, wherein the active pattern includes a third sidewall and a fourth sidewall opposite to each other in the second direction,
wherein at least one of the third sidewall or the fourth sidewall of the active pattern has a step defined by the second direction.

15. The semiconductor device of claim 12, further comprising a back gate electrode extending in the first direction and spaced apart from the word line in the second direction,
wherein the active pattern is between the word line and the back gate electrode in a plan view of the semiconductor device,
wherein a vertical level of an upper surface of the word line is higher than a vertical level of an upper surface of the back gate electrode in the third direction.

16. The semiconductor device of claim 12, wherein the bit line includes a first conductive pattern, a second conductive pattern disposed on the first conductive pattern, and a metal silicide pattern disposed on the second conductive pattern,
wherein the metal silicide pattern includes:
a first portion having a first vertical length in the third direction; and
a second portion having a second vertical length in the third direction, wherein the second vertical length is different from the first vertical length.

17. A semiconductor device comprising:
a word line extending in a first direction;
bit lines spaced apart from each other in the first direction and extending in a second direction, wherein each of the bit lines includes a first conductive pattern, a second conductive pattern disposed on the first conductive pattern, and a metal silicide pattern disposed on the second conductive pattern;
an active pattern disposed on each of the bit lines;
a first isolation pattern disposed between the first conductive patterns adjacent to each other in the first direction;
a second isolation pattern disposed on the first isolation pattern and between the second conductive patterns adjacent to each other in the first direction, between the metal silicide patterns adjacent to each other in the first direction, and between the active patterns adjacent to each other in the first direction; and
a barrier insulating pattern between the second isolation pattern and the active pattern,
wherein a width of the first isolation pattern in the first direction is greater than a width of the second isolation pattern in the first direction.

18. The semiconductor device of claim 17, wherein the barrier insulating pattern is in contact with the metal silicide pattern.

19. The semiconductor device of claim 17, wherein the barrier insulating pattern is spaced apart from the metal silicide pattern.

20. The semiconductor device of claim 17, further comprising a shielding conductive pattern disposed in the first isolation pattern.
